(19) United States
(12) Patent Application Publication
(10) Pub. No.: US 2023/0307542 A1
(43) Pub. Date: Sep. 28, 2023

(54) COPLANAR HETEROJUNCTION MONOLITHIC DEVICE AND METHOD OF FABRICATING THE SAME

(71) Applicant: Technion Research & Development Foundation Limited, Haifa (IL)

(72) Inventors: Elad KOREN, Haifa (IL); Subhrajit MUKHERJEE, Haifa (IL); Debopriya DUTTA, Haifa (IL)

(73) Assignee: Technion Research & Development Foundation Limited, Haifa (IL)

(21) Appl. No.: 18/196,024

(22) Filed: May 11, 2023

Related U.S. Application Data
(63) Continuation of application No. PCT/IL2021/051346, filed on Nov. 11, 2021.

(30) Foreign Application Priority Data
Nov. 13, 2020 (IN) 202021049700

(51) Int. Cl. H01L 29/78; H01L 29/267; H01L 29/04

(52) U.S. Cl. CPC H01L 29/78391; H01L 29/267; H01L 29/04

(57) ABSTRACT

A monolithic solid state system comprises a ferroelectric crystal and a semiconductor crystal arranged laterally to define a nanolayer having a heterojunction between the two crystals. In some embodiments, the ferroelectric crystal exhibits in-plane polarization.

### RELATED APPLICATIONS

This application is a Continuation (CON) of PCT Application No. PCT/IL2021/051346 filed on Nov. 11, 2021, which claims the benefit of priority of Indian Patent Application No. 202021049700, filed on Nov. 13, 2020. The contents of the above applications are all incorporated by reference as if fully set forth herein in their entirety.

### FIELD AND BACKGROUND OF THE INVENTION

The present invention, in some embodiments thereof, relates to a solid state system and, more particularly, but not exclusively, to a coplanar heterojunction monolithic device and method of fabricating the same.

Over the past decade, several two-dimensional (2D), beyond graphene, have been developed [Das et al., Nano Lett. 2014, 14 (5), 2861-2866; Li et al., Nat. Nanotechnol. 2014, 9 (5), 372-377; Cui et al., npj 2D Mater. Appl. 2018, 2 (1), 1-14; Jana et al., Adv. Opt. Mater. 2020, 8 (12), 2000180; Mukherjee et al., ACS Photonics 2015, 2 (6), 760-768]. These materials have atomically thin nature, stable physical form, superior gate tunability, and high-transparency.

Recently, atomically thin metal-oxides (MO) with superior physical or chemical properties have been fabricated [Netzer et al., www(DOT)doi(DOT)org/10.1007/978-3-319-28332-6; Yang et al., Nat. Mater. 2019, 18 (9), 970-976; Yang et al., Adv. Mater. Interfaces 2019, 6 (1), 1801160].

2D based planar heterojunctions offers device area with 1D type interface, which facilitates larger depletion regions and an abrupt change in electronic and optical properties [Novoselov et al., Science 2016, 353 (6298); Wang et al., Nat. Mater. 015, 14 (3), 264-265; Lyu et al., Adv. Mater. 2020, 32 (2), 1906000; Jariwala et al., Nat. Mater. 2017, 16 (2), 170-181; Li, et al. Mater. Today 2016, 19 (6), 322-335]. Various strategies have been adopted to build all 2D coplanar heterojunction, such as lateral epitaxial growth [Li et al., Science 2015, 349 (6247), 524-528; Liu et al., Science 2014, 343 (6167), 163-167], block-copolymer lithography followed by etching [Yun et al., Adv. Funct. Mater. 2018, 28 (50), 1804508], selective ion (EBL/FIB) [Stanford et al., Sci. Rep. 2016, 6 (1), 27276; Ghorbani-Asl et al., 2D Mater. 2017, 4 (2), 025078], and atomic probe patterning [Liu et al., Adv. Mater. 2017, 29 (1), 1604121; Nano Lett. 2019, 19 (3), 2092-2098]. Laser-based surface oxidation of top few layers of γ-InSe has been realized to protect the crystal surface from deterioration over time, and was further used as vertical heterojunction [Balakrishnan et al., 2D Mater. 2017, 4 (2), 025043]. Efforts have also been made to pattern on MoS₂ [Kappera et al., Nat. Mater. 2014, 13 (12), 1128-1134]. and MoTe₂ [Cho et al., Science 2015, 349 (6248), 625-628] by selective phase change using a laser-induced, resistless direct-writing process.

### SUMMARY OF THE INVENTION

According to an aspect of some embodiments of the present invention there is provided a monolithic solid state system. The system comprises a ferroelectric crystal and a semiconductor crystal arranged laterally to define a nanolayer having a heterojunction between the crystals, the nanolayer comprising at most 250 monolayers of the ferroelectric crystal.

According to an aspect of some embodiments of the present invention there is provided a monolithic solid state system. The system comprises a ferroelectric crystal and a semiconductor crystal arranged laterally to define a nanolayer having a heterojunction between the crystals, the nanolayer having a thickness of at most 500 nm.

According to some embodiments of the invention the ferroelectric crystal is polarized such that an internal electric field induced by the polarization comprises a component perpendicular to the heterojunction.

According to some embodiments of the invention a width of the heterojunction is less than 250 nm, more preferably less than 200 nm, more preferably less than 150 nm, more preferably less than 100 nm, more preferably less than 80 nm, more preferably less than 60 nm, more preferably less than 40 nm.

According to some embodiments of the invention the nanolayer is planar.

According to some embodiments of the invention the semiconductor crystal is an oxide.

According to some embodiments of the invention the oxide is formed by oxidation of the ferroelectric crystal.

According to an aspect of some embodiments of the present invention there is provided a method of configuring a solid state system. The method comprises providing the solid state system as delineated above and optionally and preferably as further detailed below; and applying an electric field to the ferroelectric crystal so as to polarize the ferroelectric crystal in a direction parallel to the nanolayer.

According to an aspect of some embodiments of the present invention there is provided an integrated circuit. The integrated circuit comprises the system as delineated above and optionally and preferably as further detailed below, and a plurality of contacts in electrical communication with the heterojunction.

According to some embodiments of the invention the integrated circuit comprises an electrode positioned to apply an electric field to the ferroelectric crystal so as polarize the ferroelectric crystal along a direction parallel to the nanolayer, wherein the applied electric field has a component perpendicular to the nanolayer.

According to an aspect of some embodiments of the present invention there is provided a diode system comprising the integrated circuit.

According to an aspect of some embodiments of the present invention there is provided a transistor system comprising the integrated circuit.

According to an aspect of some embodiments of the present invention there is provided a memory system comprising the integrated circuit.

According to an aspect of some embodiments of the present invention there is provided an imaging system comprising the integrated circuit.

According to an aspect of some embodiments of the present invention there is provided a display system comprising the integrated circuit.

According to an aspect of some embodiments of the present invention there is provided a projector display system comprising the integrated circuit.

According to an aspect of some embodiments of the present invention there is provided an identification tag system comprising the integrated circuit.

According to an aspect of some embodiments of the present invention there is provided a sensor comprising the integrated circuit.

According to some embodiments of the invention the sensor being a photodetector.

According to an aspect of some embodiments of the present invention there is provided a method of sensing. The method comprises directing light to the photodetector, and receiving electrical signal via the contacts. According to some embodiments of the invention the sensing is executed without applying bias voltage to the heterojunction of the photodetector.

According to an aspect of some embodiments of the present invention there is provided a method of fabricating a monolithic heterojunction. The method comprises: selectively irradiating a region of nanolayer having at most 250 monolayers of a ferroelectric crystal by light such as to convert the ferroelectric crystal in the region into a semiconductor crystal by photo-thermal oxidation, thereby forming a heterojunction between the semiconductor crystal in the region and the ferroelectric crystal in other regions of the nanolayer.

According to an aspect of some embodiments of the present invention there is provided a method of fabricating a monolithic heterojunction. The method comprises: selectively irradiating a region of nanolayer of a ferroelectric crystal by light such as to convert the ferroelectric crystal in the region into a semiconductor crystal by photo-thermal oxidation, thereby forming a heterojunction between the semiconductor crystal in the region and the ferroelectric crystal in other regions of the nanolayer, wherein the nanolayer has a thickness of at most 500 nm.

According to some embodiments of the invention the nanolayer comprise at most 250 monolayers of the ferroelectric crystal. According to some embodiments of the invention the nanolayer comprise at most 120 monolayers of the ferroelectric crystal. According to some embodiments of the invention the nanolayer comprise at most 100 monolayers of the ferroelectric crystal.

According to some embodiments of the invention the nanolayer has a thickness of at most 500 nm. According to some embodiments of the invention the nanolayer has a thickness of at most 400 nm. According to some embodiments of the invention the nanolayer has a thickness of at most 300 nm. According to some embodiments of the invention the nanolayer has a thickness of at most 200 nm. According to some embodiments of the invention the nanolayer has a thickness of at most 100 nm. According to some embodiments of the invention the nanolayer has a thickness of at most 50 nm. According to some embodiments of the invention the nanolayer has a thickness of at most 25 nm.

According to some embodiments of the invention the method comprises protecting a boundary of the region from the light prior to the radiation, so as to reduce a width of the heterojunction in a direction parallel to the nanolayer and perpendicular to the boundary.

According to some embodiments of the invention the method comprises growing the nanolayer.

According to some embodiments of the invention the ferroelectric crystal comprises In₂Se₃, and the semiconductor crystal comprises In₂O₃. According to some embodiments of the invention the selective irradiation is by visible light. According to some embodiments of the invention the selective irradiation is by UV light. According to some embodiments of the invention the selective irradiation is by light spanning over a visible as well as UV spectrum.

According to some embodiments of the invention the ferroelectric crystal comprises Pb(ZrₓTi₁₋ₓ)O₃. According to some embodiments of the invention x is about 0.96.

According to some embodiments of the invention the ferroelectric crystal comprises LiAlTe₂.

According to some embodiments of the invention the ferroelectric crystal comprises CuInP₂S₆.

According to some embodiments of the invention the method comprises applying an electric field to the ferroelectric crystal so as polarize the ferroelectric crystal along a direction parallel to the nanolayer.

According to some embodiments of the invention the applied electric field has a component perpendicular to the nanolayer.

According to some embodiments of the invention the region is selected such that a boundary of the region is perpendicular to the direction of the polarization.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

### BRIEF DESCRIPTION OF THE SEVERAL VIEWS OF THE DRAWINGS

Some embodiments of the invention are herein described, by way of example only, with reference to the accompanying drawings and images. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIGS. 1A-H relate to a α-In₂Se₃ layered structure. A schematic representation is shown in FIG. 1A. High-resolution (HR)-TEM micrographs of In₂Se₃ in top-view (FIG. 1B) and cross-section view (FIG. 1C) mode. FIG. 1D shows TEM image of a laser-written square box on In₂Se₃ mounted on TEM Cu-grid. FIG. 1E shows HR-TEM image acquired inside the box region in FIG. 1D exhibits crystal formations. FIG. 1F shows imaging of a single crystalline region from FIG. 1E. FIG. 1G shows atomic force microscope image of In₂Se₃ on SiO₂ substrate. The thickness of the as-grown film is found to be about 7 nm, as indicated in the height profile (FIG. 1H).

FIG. 2A shows an optical image of In₂Se₃ mounted on TEM Cu-grid (FIG. 2A). The colored boxes represent the exposed areas with different laser powers.

FIGS. 2B and 2C show elemental distribution (acquired from EDS spectroscopy) on laser-written boxes and its surrounding area for 72.85 mW/μm² (FIG. 2B) and 29.14 mW/μm² (FIG. 2C) laser illumination.

FIG. 2D shows Se-to-In and O-to-In ratios extracted from elemental mapping and plotted against laser power.

FIGS. 2E and 2F show 2D (FIG. 2E) and 3D (FIG. 2F) image of In₂O₃ overlayer on In₂Se₃ background acquired by ToF-SIMS technique. The green colour boxes indicating the laser written area.

FIGS. 2G and 2H show ToF-SIMS depth profiles for In₂O₃ (FIG. 2G) and In₂Se₃ (FIG. 2H) for different laser powers.

FIG. 3A is an optical image of laser written boxes on In2Se3 film using different illumination intensities (laser intensities are specified for each box).

FIGS. 3B and 3C show Raman mapping on a selected region for 107 cm⁻¹ (FIG. 3B) and 252 cm⁻¹ (FIG. 3C) phonon modes.

FIG. 3D shows PL mapping of the same array for 582 nm peak wavelength.

FIG. 3E shows Raman maps of a logo written on In₂Se₃ for 107 cm⁻¹ (top) and 252 cm⁻¹ (bottom) giving further evidence for the superior geometrical flexibility and good controllability to design arbitrary shapes.

FIGS. 3F and 3G show PL (FIG. 3F) and Raman (FIG. 3G) spectra, acquired for various intensities and the enhancement of characteristic peaks of In2Se3 are plotted against the irradiation intensity.

FIGS. 3H and 3I show Raman modes (FIG. 3H) and PL (FIG. 3I) integrated area vs. intensity.

FIGS. 4A and 4B show measured surface potential profiles along the pristine (FIG. 4A) and laser treated (FIG. 4B) FET channel under different applied drain bias conditions. The perpendicular dotted lines (red) indicating the metal-semiconductor interfaces.

FIGS. 4C and 4D show calculated electric field profile along the FET channel for pristine (FIG. 4C) and laser treated (FIG. 4D) samples.

FIGS. 5A and 5B are an optical image of a typical bottom-gate (bg)-FET fabricated by electron beam lithography (FIG. 5A), and a typical surface topography of the fabricated bg-FET with a schematic illustration of electrical circuitry.

FIGS. 5C-F show output (FIGS. 5C and 5E) and transfer characteristics (FIGS. 5D and 5F) of the bg-FET using as-grown In₂Se₃ film (FIGS. 5C and 5D) and of the laser written channels of the same device (FIGS. 5E and 5F).

FIG. 6A shows diode characteristics of lateral p-n heterojunction FET for various gate bias conditions. Inset presents a schematic illustration of the heterojunction fabrication.

FIGS. 6B and 6C show measured surface potential (FIG. 6B) and calculated electric field profiles (FIG. 6B), along the heterojunction FET channel, for different applied bias conditions.

FIG. 6D shows band diagram of the heterojunction FET under equilibrium condition.

FIG. 6E shows photocurrent variation as the function of gate bias. Inset shows the temporal time response under zero bias condition.

FIG. 6F shows temporal time response (at 60 V gate bias) of the heterojunction device for different illumination intensities.

FIG. 7A is a schematic set-up illusion of a growth process of In₂Se₃ using In₂O₃ and Se powder.

FIGS. 7B and 7C are optical microscope images of In₂Se₃ on mica substrate after growth (FIG. 7B) and SiO₂ substrate after wet-transfer (FIG. 7C).

FIGS. 8A and 8B are HR-TEM micrographs of as-grown In₂Se₃ exhibits good crystal quality with atomic spacings of about about 0.20 nm, attributed to the (1 1 0) along the [1120] direction (FIG. 8A), and SAED of the same also exhibiting high crystalline quality (FIG. 8B).

FIGS. 9A-C show effect of various laser exposure period and irradiation power on In₂Se₃. FIG. 9A shows optical image, and FIGS. 9A and 9B show Raman mapping 107 cm⁻¹ (FIG. 9B) and 253 cm⁻² (FIG. 9C) modes.

FIG. 10 is a schematic illustration of the laser-induced thermal annealing (photo-thermal) effect.

FIG. 11A shows surface temperature profile on 10 nm In₂Se₃ layer mounted in SiO₂/Si substrate obtained from the 3D simulation model (FIG. 11A), and

FIG. 11B shows a planar projection of the surface temperature on In₂Se₃ obtained from FIG. 11A. The temperature was estimated from the maxima of the Gaussian beam profile, taken along the white dotted line.

FIGS. 11C and 11D show time-dependent simulated temperature evolution for 10 mW (FIG. 11C), and 1 mW (FIG. 11D) laser power, for the In₂Se₃ layer of FIGS. 11A-B.

FIG. 12 shows photoluminescence spectra of In₂Se₃ for different annealing temperatures under air-atmosphere. Each PL spectrum was measured following a 30 min thermal annealing in ambience. It is observed that above 300° C., the PL emission for In₂O₃ started to become apparent. This indicates that the material transformation is dictated by thermal excitation in agreement with the modelling (see FIGS. 11A-D) and control experiments (see FIGS. 9A-C).

FIG. 13 shows line profile for Se atomic wt % across the In₂O₃—In₂Se₃ interface as estimated from STEM-EDS analysis.

FIGS. 14A-D show an optical image of In₂Se₃ film on SiO₂ surface (FIG. 14A), and Raman mapping of the selected region for peak 107 (FIG. 14B), 205 (FIG. 14C) and 252 (FIG. 14D) cm⁻¹, indicating that without strong (above the threshold power) laser illumination, the In₂Se₃ films retained their characteristics properties. There is no evidence of —Se₈— rings formation without reasonable laser illumination (FIG. 14D).

FIG. 15A shows Kelvin-probe force microscopy (KPFM) image acquired on the same area, where PL and Raman mapping was performed;

FIG. 15B shows variation of the potential on the exposed area compared to the background In₂Se₃ film plotted as the function of irradiated laser intensity,

FIGS. 15C and 15D are optical (FIG. 15C) and KPFM (FIG. 15D) images of a logo;

FIGS. 15E and 15F are optical (FIG. 15E) and KPFM (FIG. 15F) images of alphabets written using optothermal effect on In₂Se₃, establishing the flexibility of the method to design arbitrary shaped circuitry and offer the prospect for several technological applications, such as on-demand electronic circuitries, patterns/design parallel stitching etc.

FIG. 16A shows surface potential map of the In₂Se₃ on SiO₂ surface after selective exposure. The white dotted box region was exposed. The green dashed line separates the In₂Se₃ from the SiO₂ background. The left side of green dashed lines represents the base SiO₂, whereas the right side represents In₂Se₃ layers.

FIG. 16B shows potential profiles obtained along the arrow line of FIG. 16A (line colors kept same as corresponding profile color for easy understanding).

FIGS. 17A-C show surface potential mapping of fabricated FETs, consisting the channel materials as, the pristine In₂Se₃ (FIG. 17A) converted In₂O₃ (FIG. 17B) and co-planer heterojunction of In₂Se₃—In₂O₃ (FIG. 17C), under equilibrium condition. The perpendicular red-coloured dotted lines are indicating the metal-semiconductor interfaces. The brownish area presents the converted In₂O₃, while the whitish area retained as In₂Se₃.

FIGS. 18A and 18B show, respectively, variation of localized surface potential (measured at center of FET channel), and estimated electric field (in FET channel), as a function of applied bias. The measured surface potential and estimated electric field are progressively increasing with applied bias for both cases, but are significantly smaller for illuminated FET pointing to higher carrier flow due to higher conductivity of In₂O₃, as well as Schottky barrier modification.

FIG. 19 shows deduced conductivity of the pristine channel and the laser irradiated channel using KPFM, as a function of applied bias, demonstrating nearly two-order enhancement.

FIGS. 20A and 20B show time-dependent photo-response under periodic illumination for different gate bias (FIG. 20A), calculated responsivity and detectivity of the fabricated heterojunction plotted against the applied gate bias (FIG. 20B).

FIGS. 21A-C show photo-switching behaviors of In₂Se₃ (FIG. 21A), In₂O₃ (FIG. 21B) and In₂Se₃—In₂O₃ (FIG. 21C) heterojunction devices, under periodic illumination. Each graph is color-coded as the incident light color. The limits for Y axes scale are kept same for all wavelengths for easy comparison.

FIG. 22 shows wave-length dependent photo-responsivity (solid symbols) and photo-detectivity (open symbols) data for all three devices. The dotted lines are drawn for eye-guiding.

FIG. 23 is a schematic flowchart of a wet-transfer method of In₂Se₃ from growth substrate to a targeted substrate.

FIG. 24 shows comparative Raman spectra for polystyrene (PS), In₂Se₃ with PS residues and In₂Se₃ after PS removal, on SiO₂ substrate.

FIG. 25 shows PL spectra of CVD-grown In₂Se₃ on growth (mica) substrate using the excitation wavelength of 532 nm (top) and 405 nm (bottom). The arrow indicates the expected position of graphitic Raman signals using 405 nm excitation.

FIG. 26A is an optical image of In₂Se₃ on growth substrate (mica);

FIG. 26B shows PL spectra, acquired for different laser powers;

FIG. 26C shows optical image of the laser written box (4×4 μm) on In₂Se₃ film on growth substrate;

FIG. 26D shows PL for 582 nm, and

FIGS. 26E and 26F show, respectively, Raman maps for 107 and 252 cm⁻¹ on the same box.

FIG. 27 is a schematic illustration of a cross-sectional view of a solid state system, according to some embodiments of the present invention.

FIG. 28 is a schematic illustration of a configurable solid state system, according to some embodiments of the present invention.

FIG. 29 is a schematic illustration of a top view of an integrated circuit, according to some embodiments of the present invention.

FIG. 30 is a flowchart diagram describing suitable for fabricating a monolithic heterojunction according to various exemplary embodiments of the present invention.

### DESCRIPTION OF SPECIFIC EMBODIMENTS OF THE INVENTION

The present invention, in some embodiments thereof, relates to a solid state system and, more particularly, but not exclusively, to a coplanar heterojunction monolithic device and method of fabricating the same.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

FIG. 27 is a schematic illustration of a cross-sectional view of a solid state system 10, according to some embodiments of the present invention. System 10 preferably comprises a ferroelectric crystal 12 and a semiconductor crystal 14, arranged laterally to define a nanolayer 16 having a heterojunction 18 between crystals 12 and 14. Nanolayer 16 is typically supported by a substrate 20, such as, but not limited to, a mineral substrate, e.g., a mica substrate, or an insulating oxide substrate, e.g., a SiO₂ substrate or the like. Heterojunction 18 is preferably a p-n junction.

System 10, including crystals 12 and 14, heterojunction 18, and optionally and preferably also substrate 20 is preferably monolithic.

As used herein, “monolithic” refers to an object which is provided as a single, unitary piece formed or constructed of materials without joints or seams, such that none of its components can be separated without substantially damaging the component.

As used herein, a “nanolayer” generally refers to a structure, optionally and preferably a planar structure, which is made of a solid substance, and which, at any point along its surface, has a thickness less than 1 micron, or at most 500 nanometers, or at most 400 nanometers, or at most 300 nanometers, or at most 200 nanometers, or at most 150 nanometers, or at most 100 nanometers, or even at most 70 nanometers, at most 50 nanometers, at most 20 nanometers, or at most 10 nanometers.

In some embodiments of the present invention nanolayer 16 comprises at most 250 monolayers or at most 200 monolayers or at most 120 monolayers or at most 100 monolayers or at most 80 monolayers or at most 40 monolayers or at most 20 monolayers or at most 10 monolayers of ferroelectric crystal 12.

The width of heterojunction 18, as measured along a line perpendicular to the interface between crystals 12 and 14 is optionally and preferably also nanometric. In some embodiments of the present invention the width of heterojunction 18 is less than 250 nm, or less than 200 nm, or less than 150 nm, or less than 100 nm, or less than 80 nm, or less than 80 nm, or less than 60 nm, or less than 40 nm or less than 20 nm.

The width of heterojunction 18 is defined as the width of a transition region between crystals 12 and 14, along which the crystalline structure varies from a structure that is predominantly ferroelectric to a structure that is predominantly semiconductor. For example, the width can be the width of a region along which the ratio R between the number of ferroelectric crystal cells and the number of semiconductor crystal cells varies from about 3 (e.g., 75% ferroelectric and 25% semiconductor) to about ⅓ (e.g., 25% ferroelectric and 75% semiconductor).

Semiconductor crystal 14 is optionally and preferably an oxide. In various exemplary embodiments of the invention semiconductor crystal 14 is an oxide that is formed by oxidation of ferroelectric crystal 12. These embodiments are advantageous from the standpoint of simplicity of fabrication. For example, monolayer 16 can initially include ferroelectric crystal 12 without semiconductor crystal 14 and any heterojunction, and semiconductor crystal 14 can be formed by selectively converting regions of ferroelectric crystal 12 into semiconductor crystal 14, thus forming also heterojunction 18 at the interface between the pristine regions of ferroelectric crystal 12 and the converted regions of the semiconductor crystal 14. This example was demonstrated by the Inventors in an experiment in which a scanning laser probe was used to locally convert In₂Se₃ into In₂O₃, which showed a significant increase in carrier mobility and transforms the metal-semiconductor junctions from Schottky to ohmic type.

Thus, according to some embodiments of the present invention ferroelectric crystal 12 comprises In₂Se₃, and semiconductor crystal 14 comprises In₂O₃. It is envisioned, however, that many other combinations of crystals can form a suitable heterojunction therebetween, and the present embodiments contemplates any such combinations of crystals. As representative examples, ferroelectric crystal 12 can comprise lead zirconium titanate (e.g., Pb(ZrₓTi₁₋ₓ)O₃, where x is a number between 0 and 1 (not inclusive), e.g., about 0.96), or LiAlTe₂, or CuInP₂S₆, and the semiconductor crystal 14 can be an oxide formed by oxidizing these ferroelectric crystals.

A particular advantage of system 10 is that layer 16 is nanometric and thus facilitate in-plane polarizability of semiconductor crystal 14. Thus, according to some embodiments of the present invention ferroelectric crystal 14 is polarized such that an internal electric field induced by the polarization comprises a component (shown by arrow 22) perpendicular to heterojunction 18. These embodiments are particularly (but not exclusively) useful in applications in which system 10 is used as a photo-responsive system, e.g., as a light detector or the like, wherein the in-plane polarization in crystal 12 can effectively increase the amount of collected charge and the measured photocurrent.

It was surprisingly found by the inventors that ferroelectric crystal 14 can be polarized along a predetermined in-pane direction by applying an external electric field to crystal 14 in a direction that has a component perpendicular to nanolayer 16.

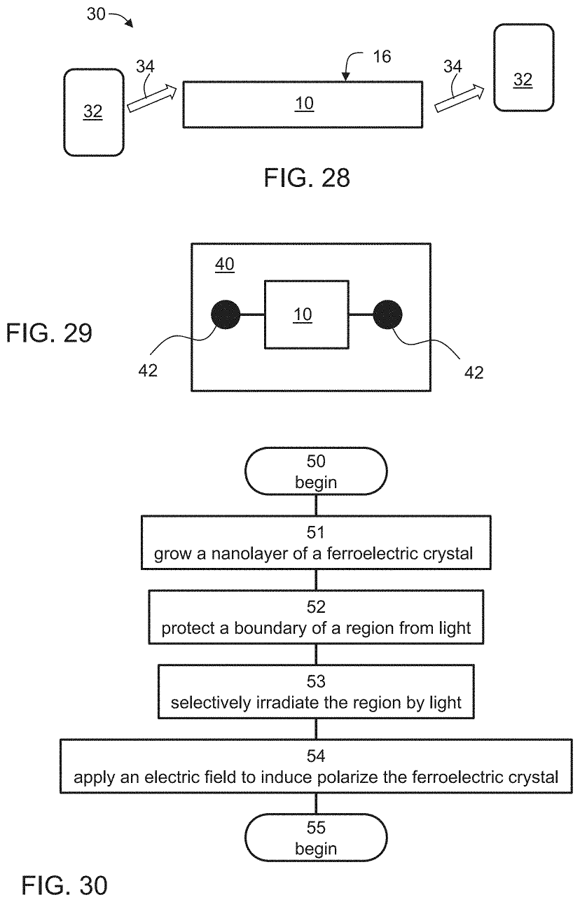

The extent and/or direction of the polarization can be configurable. FIG. 28 is a schematic illustration of a configurable system 30, which comprises system 10 and one or more electrodes 32 positioned to apply an external electric field 34 to ferroelectric crystal 12 (not specifically shown, see FIG. 27) so as polarize the ferroelectric crystal 12 along a direction parallel to nanolayer 16, wherein the applied electric field 32 has a component perpendicular to nanolayer. System 30 is advantageous since the extent and/or direction of the polarization can be tailored for the specific application for which the system 30 is designed. More preferably, at least one parameter (extent, direction) of the polarization can be re-adjusted. For example, the system can be employed with one polarization, and then the parameter(s) can be varied to a different value before employing the system again.

System 10/30 is typically incorporated in an integrated circuit. FIG. 29 is a schematic illustration of a top view of an integrated circuit 40, which comprises system 10 and a plurality of contacts in electrical communication with heterojunction 18 (not specifically shown, see FIG. 27). Integrated circuit 40 can serve, or be employed in, any one of many electronic systems, including, without limitation, a diode system, a transistor system (e.g., a FET system), a memory, an imaging system, a display system, a projector display system, an identification tag system, a sensor (e.g., a photodetector), and the like. For example, when integrated circuit 40 serves as a diode, heterojunction 18 can be a p-n junction of the diode, and a pair of contacts 42 can be used to contact crystals 12 and 14 at both sides of heterojunction 18 to allow applying a forward or reverse voltage to the p-n junction. When integrated circuit 40 serves as a FET, crystals 12 and 14 and heterojunction 18 can enact a channel of the FET, wherein a pair of contacts contacting crystals 12 and 14 enact a source and a drain. An additional contact can be used as a gate. For example, a gate contact can be formed on substrate 20 thus forming a bottom-gate FET. When integrated circuit 40 serves as a sensor, crystals 12 and 14 can be placed in an environment such that a change in the environment (e.g., electromagnetic change, such as, but not limited to, exposure to light, or a temperature change, or a strain) result in flow of charge carriers through heterojunction 18, producing a detectable electrical signal at the contacts. In some embodiments of the present invention the flow of charge carriers is established by means of the component 22 of the internal electric field across heterojunction 18, and the sensing is executed without applying bias voltage to heterojunction 18.

FIG. 30 is a flowchart diagram of a method suitable for fabricating a monolithic heterojunction according to various exemplary embodiments of the present invention. It is to be understood that, unless otherwise defined, the operations described hereinbelow can be executed either contemporaneously or sequentially in many combinations or orders of execution. Specifically, the ordering of the flowchart diagrams is not to be considered as limiting. For example, two or more operations, appearing in the following description or in the flowchart diagrams in a particular order, can be executed in a different order (e.g., a reverse order) or substantially contemporaneously. Additionally, several operations described below are optional and may not be executed.

The method begins at 50 and optionally and preferably continues to 51 at which a nanolayer of a ferroelectric crystal is grown. Operation 51 can be executed using any growing technique known in the art, such as, but not limited to, vapor deposition, for example, chemical vapor deposition (CVD). The ferroelectric crystal can be of any of the types described above, and the thickness of the nanolayer can b e as further detailed hereinabove. The method optionally and preferably continues to 52 at a boundary of a region of the ferroelectric crystal is protected from light. Such protection can be by masking the boundary of the region with a substance that substantially blocks the light, such as, but not limited to, hBN or Au. The advantage of operation 52 is that it allows controlling the width of the heterojunction and improving its sharpness.

The method preferably continues to 53 at which the region is selectively irradiated by light such as to convert the ferroelectric crystal in the region into a semiconductor crystal. The wavelength of the light is selected such as to ensure conversion of the ferroelectric crystal into the semiconductor crystal by photo-thermal oxidation. In some embodiments of the present invention the light is visible light, in some embodiments of the present invention the light is UV light, and in some embodiments of the present invention the light spans over a range [λ₁, λ₂] of wavelengths, wherein λ₁ is within a visible spectrum and λ₂ is within a UV spectrum.

Operation 53 forms a heterojunction between the semiconductor crystal in the region and the ferroelectric crystal in other regions of nanolayer. In some embodiments of the present invention the method continues to 54 at which an electric field is applied to the ferroelectric crystal so as polarize the ferroelectric crystal along a direction parallel to nanolayer. Preferably, the applied electric field has a component perpendicular to nanolayer. The irradiated region is optionally and preferably selected such that at least a portion of the region's boundary is perpendicular to the direction of the polarization.

The method ends at 55.

As used herein the term “about” refers to ±10%

The terms “comprises”, “comprising”, “includes”, “including”, “having” and their conjugates mean “including but not limited to”.

The term “consisting of” means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Various embodiments and aspects of the present invention as delineated hereinabove and as claimed in the claims section below find experimental support in the following examples.

### Examples

Reference is now made to the following examples, which together with the above descriptions illustrate some embodiments of the invention in a non limiting fashion.

### Coplanar Heterojunction Monolithic Devices on 2D In₂Se₃

The lateral heterojunction arrays within two-dimensional (2D) crystals of the present embodiments can be used to fabricate high-density, ultrathin electro-optical integrated circuits, although the assembling of such structures remains elusive. This Example demonstrates a rapid, scalable and site-specific integration of lateral 2D heterojunctions arrays using few-layers of indium selenide (In₂Se₃). The Inventors used a scanning laser probe to locally convert In₂Se₃ into In₂O₃, which shows a significant increase in carrier mobility and transforms the metal-semiconductor junctions from Schottky to ohmic type. In addition, a lateral p-n heterojunction diode within a single nanosheet is demonstrated and utilized for photo-sensing application. The method of this Example can be used to form high-yield, site-specific formation of lateral 2D In₂Se₃—In₂O₃ based hybrid heterojunctions for realizing nanoscale devices with multiple advanced functionalities.

### Introduction

Continuous quest for two-dimensional (2D) materials beyond graphene has led to the discovery of several emerging 2D materials over the past decade becoming one of the most popular topics in materials research.¹⁻⁵ Their atomically thin nature combined with stable physical form, superior gate tunability and high-transparency are points of distinction. Despite tremendous advancement on transition metal-dichalcogenides (TMD), 2D non-transitional metal-chalcogenides are sparsely explored. Indium selenide (In₂Se₃), a comparatively novice member in the 2D family comprises multiple phases (α, β, γ, δ and κ) and crystal structures, is advantageous due to optical and electrical properties such as, phase tunable bandgap, high dielectric constant, interlayer couplings and intercorrelated in-plane and out-of-plane structural polarizability, added to its functional diversity.⁶⁻¹⁰ On contrary, stoichiometric In₂O₃, a wide bandgap (about 3.4 eV) n-type UV absorber with high carrier mobility and conductivity has been widely used for UV-detectors/emitters, optical window, thin-film transistors (TFT) and memristors.^{11,12} While increasing demand of short-channel TFT and high-density storage motivates to explore 2D metal-oxides (MO), the strong interlayer interaction and presence of surface dangling bonds results in structural instability, often made it difficult to produce. Nevertheless, progress has been made recently to form atomically thin MO (Pd₅O₄ RhO₂, TiO₂, SrTiO₃ etc.) with superior physical/chemical properties.¹³⁻¹⁵ However, the 2D form of In₂O₃ was not achieved heretofore.

It is recognized that formation of heterostructure allows utilization of 2D semiconductors as basic building blocks for advanced optoelectronics. Coupling between wide and narrow bandgap materials is be beneficial for optoelectronics as it can cover wider spectral regime. Additionally, the staggered band offset at heterointerfaces ensures effective and rapid charge separation. It is also noted that 2D based planar heterojunctions offers device area with 1D type interface, which facilitates larger depletion regions and an abrupt change in electronic and optical properties, making them useful for many related applications, which up to now have been extremely challenging to achieve.¹⁶⁻²⁰ It is also noted that owing to the large lattice mismatch (about 60%) between α/β-In₂Se₃ and In₂O₃, their heterostructure growth without interfacial defects is highly challenging.

To date, various strategies have been adopted to build all 2D coplanar heterojunction, such as lateral epitaxial growth,^{21,22} block-copolymer lithography followed by etching,²³ selective ion (EBL/FIB)^{24,25} or atomic probe^{26,27} patterning. However, the Inventors found that epitaxial growth process provides non-uniform spatial control, concentric junction and boundary layer diffusion, whereas vapour or solution-phase ex-situ doping²⁸ globally dopes the entire device, making them detrimental to achieve an abrupt junction. Contrarily, block copolymer lithography^{23,29} or optical lithography³⁰ followed by plasma/RIE etching involved multistep fabrication process along with the use of sacrificial resist layer and plasma treatment leads to undesired contaminations, thus resulting in significantly degraded properties. Direct writing using focused particle beam^{24,25} or physical probe^{26,27} enables precise nanometer-scale heterojunctions with higher accuracy, but the energetic ions bombardment can introduce unintentional impurity and significantly ruin the structural integrity. Additionally, very low-throughput, high instrumental cost and complex operation limited the process for rapid prototyping. Previously, laser-based surface oxidation of top few layers of γ-InSe has been realized to protect the crystal surface from deterioration over time, and was further used as vertical heterojunction.³¹ Lately, efforts have been made to pattern on MoS₂³² and MoTe₂³³ by selective phase change using a laser-induced, resistless direct-writing process, which shows promise for lateral junctions engineering.

This Example demonstrates a scalable direct writing approach of monolithic integrated circuits on 2D In₂Se₃ layered semiconductor using a visible light probe. In particular, by selective illumination, the Inventors achieved spatially resolved distinct optical and electrical properties by introducing In₂O₃ into In₂Se₃ host layer. To understand the dynamics of the laser-induced opto-thermal effect on In₂Se₃ flakes and calibrate the conversion process as a function of illumination intensity, detailed in-depth microscopic (HRTEM, AFM and KPFM) and spectroscopic (Raman, PL and ToF-SIMS) investigations have been carried out. Current-voltage characteristics and surface potential imaging were used to study the electronic properties of pristine and treated In₂Se₃ thin films. Furthermore, planar p-n heterostructure Field effect transistors (FETs) were fabricated, and their overall electrical and photo-response characteristics are presented. The fabricated heterojunctions exhibit excellent photodetection characteristics, even without applying external bias. The demonstrated one-step, cost-effective and resist-less nanopatterning method to create high-quality, impurity-free coplanar p-n heterojunctions by using the opto-thermal effect is useful to directly write “on-demand” circuitry on 2D semiconductors. Moreover, according to some embodiments of the present invention the irradiation intensities are controlled so as to convert the topmost layers to create a vertical p-n heterojunction. The experimental results shown below demonstrate technological prospect for many 2D lateral heterojunctions construction and can be used in next-generation 2D heterostructures based nanoelectronics.

### Results

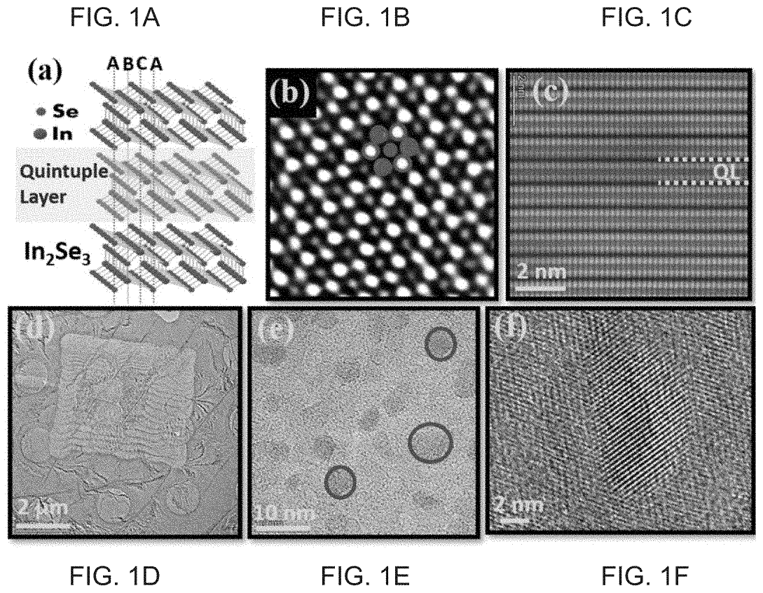

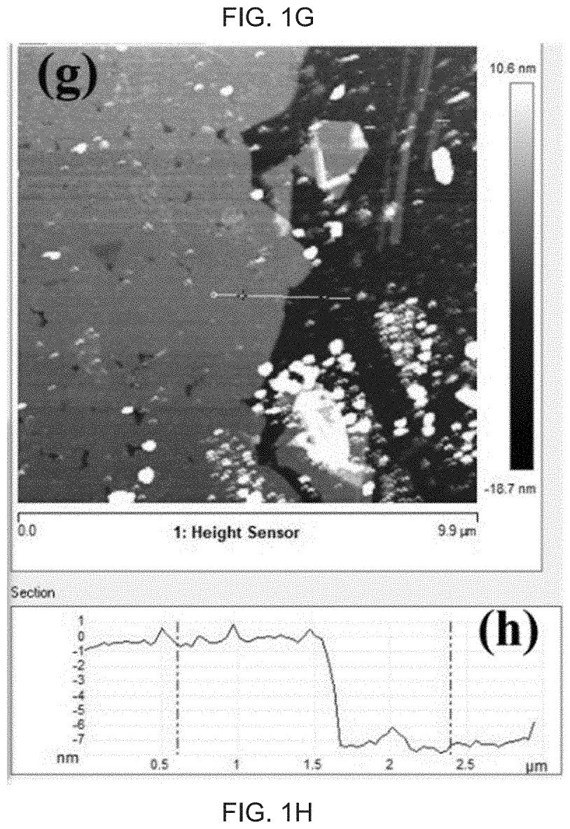

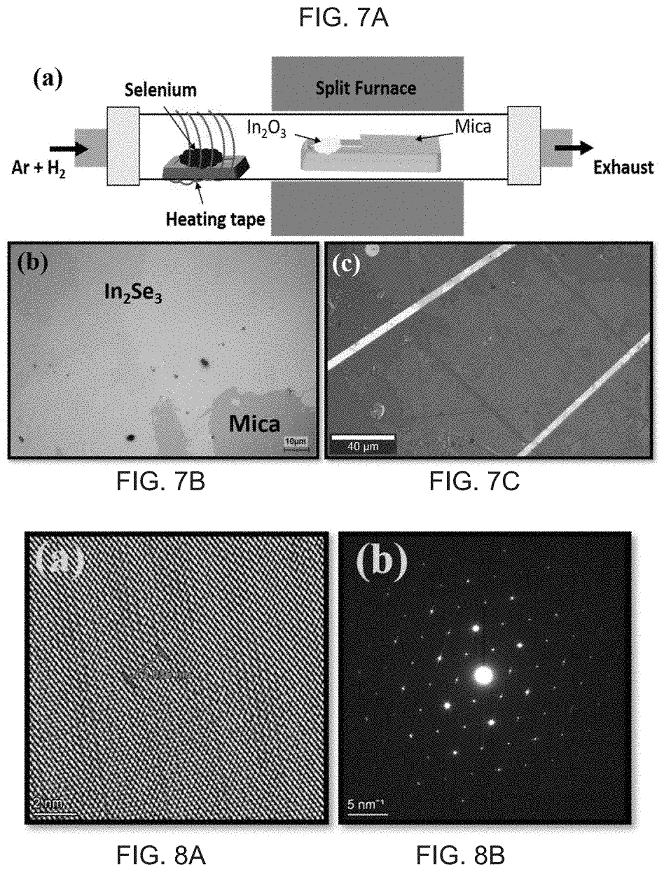

Wafer-scale, few layers In₂Se₃ film were grown by chemical vapour deposition (CVD) method, and the details of growth parameters and process flow are presented in the method section. A typical growth set-up and the optical image of as-grown In₂Se₃ are illustrated in FIGS. 7A-C. The model crystal structure of α-In₂Se₃ is presented in FIG. 1A where each monolayer is composed of five atomic layers of alternating Se and In atoms attached via covalent bonds and individual layers are vertically stacked via weak van-der-Waals forces. Along the out-of-plane direction, the atoms are arranged in ABBCA sequence. In each monolayer, the lower three Se—In—Se sub-atomic groups forms a regular tetrahedral structure, while the upper Se—In—Se sub-groups forms the octahedral structure. Thus, the middle Se layer has different environments concerning its neighbouring layers which breaks the central inversion symmetry, thereby producing the electric polarization. To investigate the crystal structure of as-grown and laser irradiated In₂Se₃, high-resolution transmission electron microscopy (HRTEM) was carried out. The atomically resolved HRTEM micrograph acquired on pristine In₂Se₃ presents the top-view of the crystal plane with a hexagonal honeycomb arrangement (FIG. 1B). The arrangement of the In and Se atoms indicating typical ABBCA stacking, thus support the α-In₂Se₃ growth along the [0001] direction (circular regions in FIG. 1B). Cross-sectional HRTEM view is presented in FIG. 1C, where the yellow dotted lines mark one monolayer thickness i.e. about 1 nm. FIG. 1D displays the laser exposed few-layers In₂Se₃, where a distinguishable square in the middle represents the laser illuminated area. A magnified image of the treated area is presented in FIG. 1E. The crystalline dark circular area (red circle marks) indicates the formation of In₂O₃ crystal inside the In₂Se₃ matrix. A high-resolution image reveals well-resolved boundaries between converted and pristine regions where the crystalline domain has an interplanar lattice spacing of about 0.29 nm corresponding to the (222) crystal planes of cubic In₂O₃ (FIG. 1F).³⁴ The pristine region located away from the illuminated spot also consists of crystalline lattice structure with a spacing of about 0.20 nm, attributed to the (110) planes of In₂Se₃ along the [1120] direction (FIG. 8A).³⁵ Selected area diffraction pattern (SAED) of the pristine film exhibits six-fold rotational symmetric diffraction, showing the high crystalline quality of the sample (FIG. 8B). The morphology and thickness of the In₂Se₃ film after transfer to a SiO₂/Si substrate, inspected by atomic force microscopy (AFM), exhibited high spatial homogeneity and film thickness of about 7 nm, (about 7 individual layers), respectively (FIGS. 1G-H).

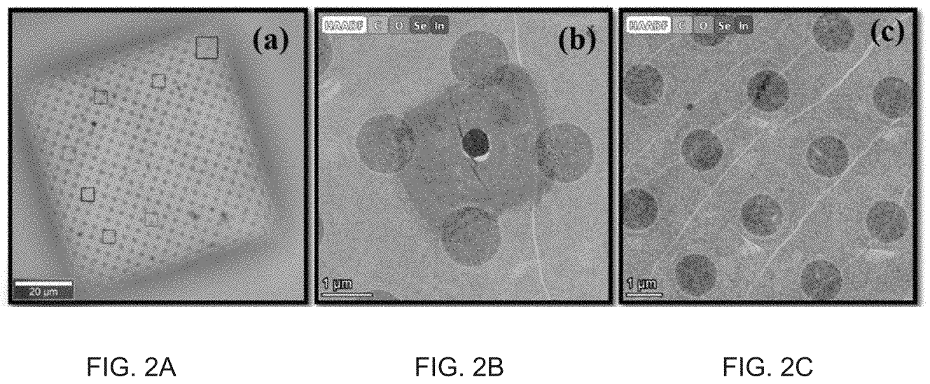

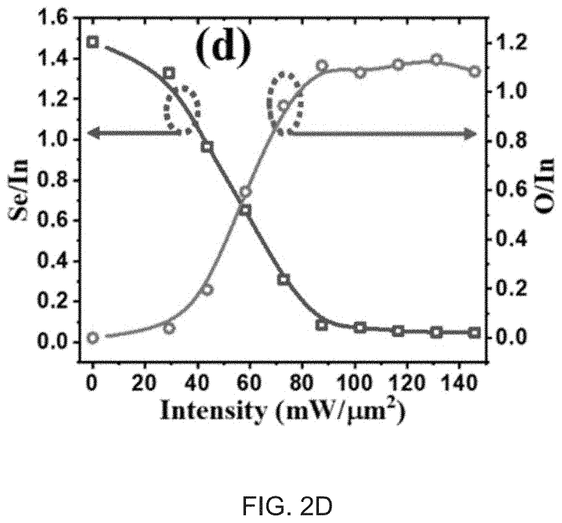

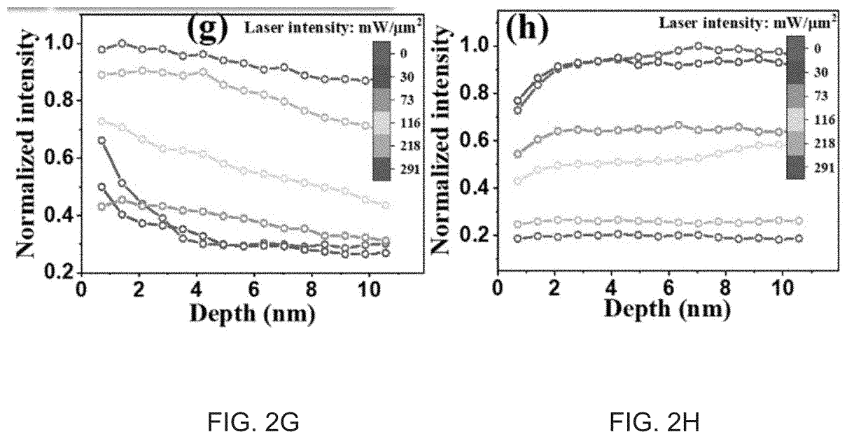

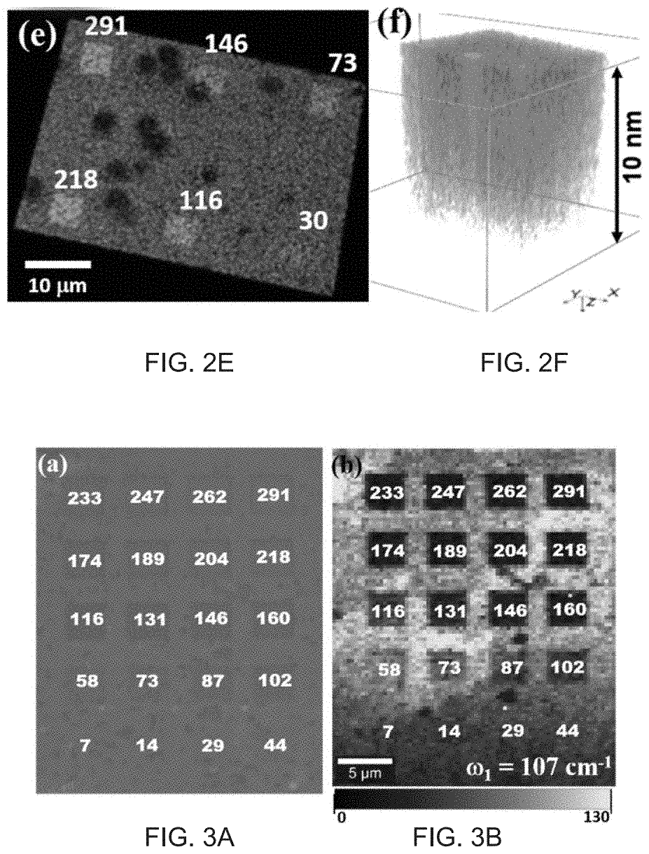

A quantitative analysis of the chemical compositions following the conversion process from In₂Se₃ to In₂O₃ through laser irradiation using different intensities is examined through energy-dispersive X-ray spectroscopy (EDS) equipped in STEM facility. FIG. 2A exhibits the optical image of In₂Se₃ layers mounted on a TEM grid, where the coloured boxes represent the illuminated areas with gradually increasing laser intensities starting from 7.28 mW/μm² to 145.70 mW/μm². The combined EDS elemental distributions, for 72.85 mW/μm² and 29.14 mW/μm² laser intensities, achieved by over layering the individual C, O, Se and In elements mapping, are presented in FIGS. 2B and 2C, respectively. The EDS mapping images show both the pristine and photo-thermally converted O-rich regions of In₂Se₃ layer, reveal the homogenous in-plane distribution of elements. The enhanced oxygen signals at the illuminated area confirm the local structural conversion. The extracted ratios of In/Se and In/O as a function of irradiated intensity were calculated using the corresponding EDS maps (FIG. 2D).

Prior to light illumination, the sample maintained its stoichiometric ratio of In₂Se₃, which is 3:2 (for Se/In), however after illumination Se content decreased, while 0 content was enriched. It is noted that, even at high power (>146 mW/μm²), a small signal of Se is still present. The chemical composition variation, along the film thickness, is analyzed by time-of-flight secondary ion mass spectroscopy (ToF-SIMS) (FIGS. 2E-H). The 2D overlayer mapping of In₂O₃ on top of In₂Se₃ confirms the presence of detectable quantities and homogeneous distribution of In₂O₃ within the illuminated area (FIG. 2E). The 3D rendering overlay of In₂O₃ inside In₂Se₃ (FIG. 2F) demonstrates that while low laser power (<116 mW/μm²) only converts the upper surface (top few layers), stronger illumination (>116 mW/μm²) converts the complete In₂Se₃ film, indicating the high-anisotropic nature of the method of the present embodiments. To investigate the stoichiometry of In₂O₃ and In₂Se₃ with respect to the film thickness for different illuminations, elemental depth profiling was carried out, and their normalized counts vs. depth are presented in FIGS. 2G and 2H, respectively. The plots indicate that the pristine film surface has nominal oxygen contamination, whereas the underneath layers (below 2 layers, as the monolayer thickness is about 1 nm) maintain proper stoichiometry. It is noted that for 116 mW/μm² exposure, the conversion process was absent, in agreement with STEM-EDS mapping. The depth profile analysis reveals that as the laser power gradually increased, the pristine In₂Se₃ film undergoes a gradual conversion reaching to the complete conversion above 116 mW/μm², in agreement with EDS results. Adjustment of the laser power below 116 mW/μm² can be used to control the formation of a vertical Indium sub-oxide junction in the 2D material.

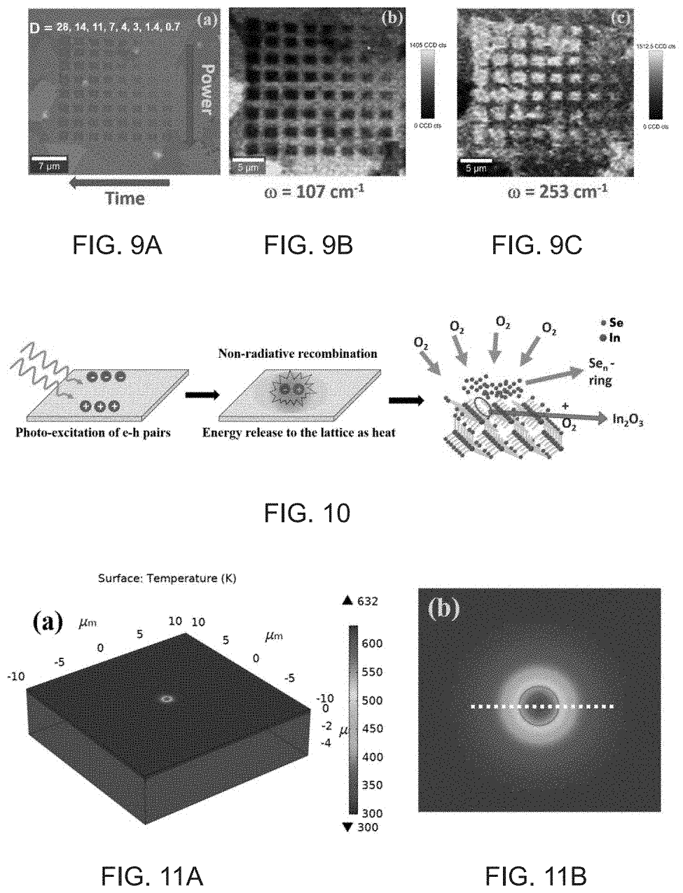

To address the underlaying mechanism of the material's conversion, the Inventors performed a time and power dependent laser illumination on In₂Se₃ and the results are depicted in FIGS. 9A-C. It has been observed that for low power and short time exposures results negligible optical heating, suggesting under dose for the patterning. Interestingly, low power and prolonged exposure leads to geometrical broadening of the exposed area identified as overdose for the desired structure. Therefore, moderate power (>5-6 mW) and low-exposure time is optimum to engineer in-plane heterostructure devices. Moreover, geometrical broadening indicates that the heat dissipation mostly takes place at the cross-plane direction and has strong time-dependent thermal anisotropy for heat conduction, which has been explained by using finite element method (FEM) based simulation model.

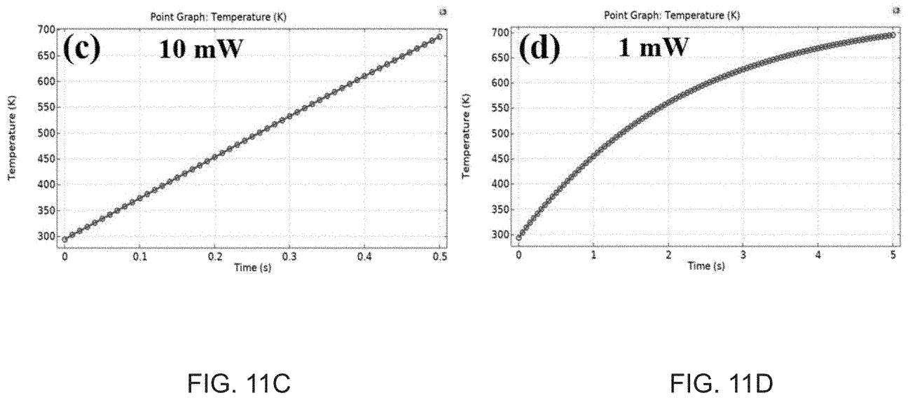

The localized temperature rise (ΔT) with function of illumination time, for different optical power (P) was estimated and depicted in FIGS. 11A-D. Briefly, the mechanisms for laser-induced local introduction of In₂O₃ domain into In₂Se₃ layers can be described by photo-thermal annealing effect, as schematically illustrated in FIG. 10. When a focused laser beam is irradiated with sufficient energy of hv=2.33 eV (higher than the material's bandgap of 1.43 eV), the In₂Se₃ accomplishes optical absorption that results in higher electron population in conduction band. The excited electrons can decay by non-radiative recombination and the excess energy is released as thermal energy which is subsequently transferred to In₂Se₃ lattice. At a particular stage, the local laser heating can break the atomic bonds and destabilize the crystal lattice by knocks out the Se atoms from the In₂Se₃ structure leaving behind stable Se vacancies as active nucleation cites. It is noted that the ToF-SIMS result shows no evidence of selenium oxide, indicating that Se tends to desorb from the surface leaving behind nucleation sites for O-absorption; as creation of a Se vacancy is energetically favourable (about 20-30 meV) as compared to generating an In vacancy (about 480 meV).^{36,37} Consequently, oxygen molecules diffuse in and occupy the Se vacancies to form a stabilized In—O bond through oxidation. The optically created Se vacancy and the resulting conversion is irreversible and stable. Moreover, the high thermal anisotropy and poor thermal dissipation in 2D In₂Se₃ (<10 nm) results in significant local temperature increment, can thrust the photo-patterning phenomena.³⁸

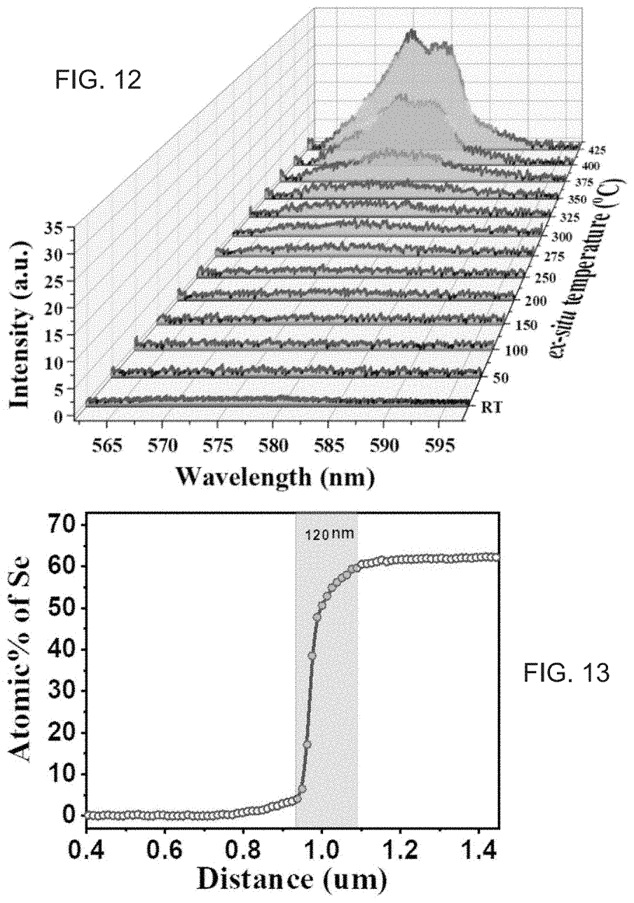

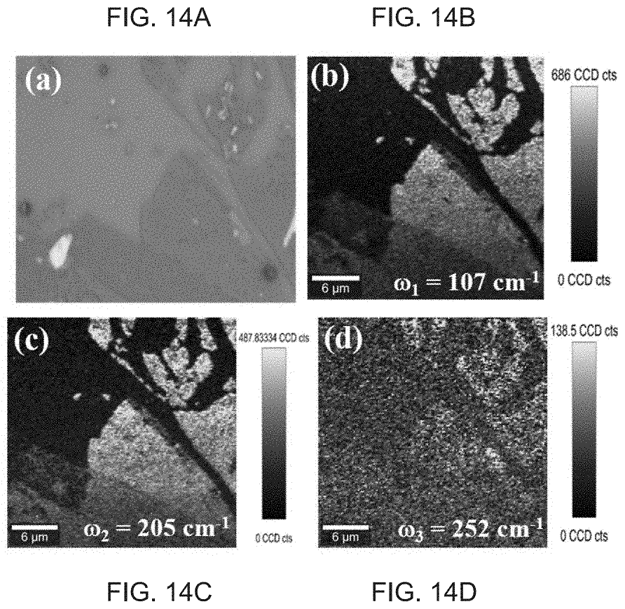

To further support the proposed mechanism, the Inventors considered an oven-annealing study that supports the photo-thermal annealing effect [FIG. 12], but the method is inefficient for selective patterning. The interfacial junction between the two materials may influence device applications. Therefore, the Inventors performed the STEM-EDS analysis across the exposed-unexposed junction and in-plane junction width was found to be quite large (about 120 nm), as determined by the gaussian beam effect (FIG. 13). However top, masking with hBN or Au, on In₂Se₃ to locally protect areas from oxygen access during laser irradiation, could be a viable approach to realize nm sharp in-plane heterojunctions.^{31,39} Moreover, laser illumination on hBN capped α-In₂Se₃ can transform to the β phase.⁴⁰

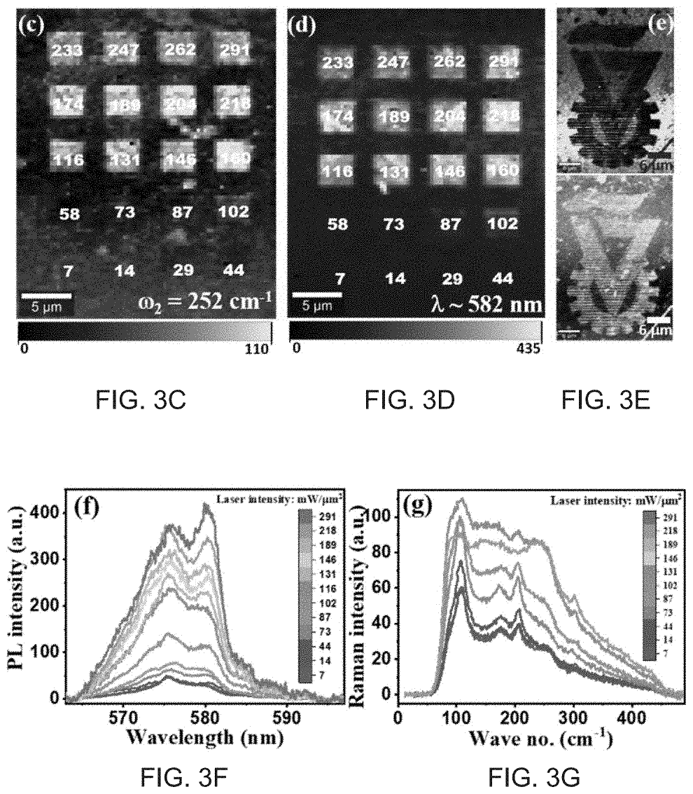

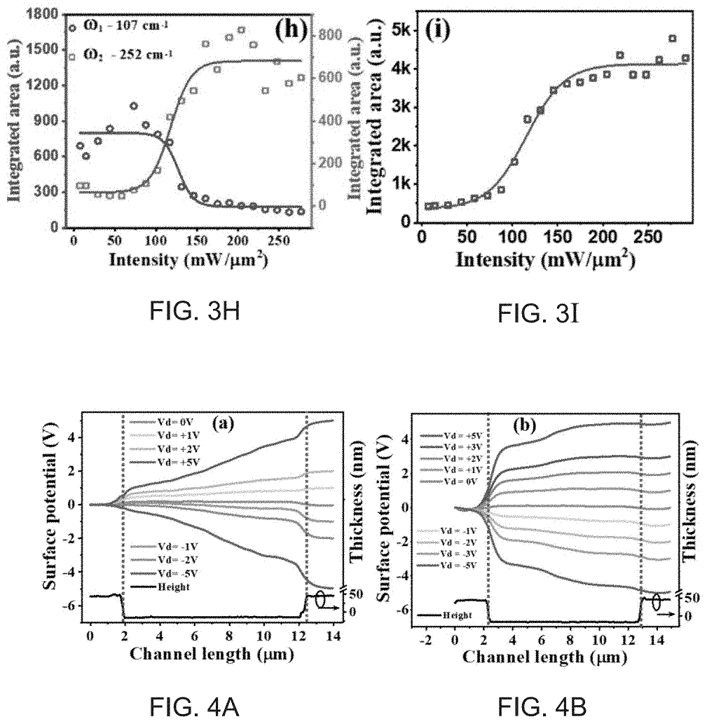

Optical images of the flakes before and after selective laser exposures reveal a distinguishable change of contrast (FIG. 3A). Photoluminescence (PL) and Raman spectroscopies were employed to monitor the crystal conversion at different illuminations. The most prominent Raman peaks, observed at 107 cm⁻¹, 176 cm⁻¹ and 205 cm⁻¹, are attributed to A₁(LO+TO), A₁(TO) and A₁(LO) symmetry modes, indicating that the pristine In₂Se₃ sample belongs to α-phase group.⁹ A small signal at 252 cm⁻¹ corresponds to the vibrational mode of —Se— bridge defect with eight-member ring formations (Ses rings).^{6,41} The corresponding Raman maps for the A₁(LO+TO) mode and Se₈-rings are presented in FIGS. 3B and 3C, respectively. Uniform Raman & PL maps indicate a spatial homogeneity of the 2D layers both before and after the conversion (FIGS. 3B-D). Moreover, both studies show that the two different compositions are well-stitched by edge-to-edge manner within the same plane.

Room-temperature PL emission spectra of the pristine and exposed areas (FIG. 3F) show no indication for band-edge PL of the few-layered α-In₂Se₃ (at about 830 nm),⁶ suggesting the presence of surface oxidation,^{42,43} in agreement with the presented ToF-SIMS data. Without wishing to be bound to any specific theory, it is believed that the PL signal originates from the oxygen-defects states. Moreover, PL emission becomes significantly stronger with higher illumination intensities is likely due to the increased oxidation within the In₂Se₃ film. Furthermore, the characteristic Raman modes of In₂Se₃ become diminished with higher laser intensity (FIG. 3G). FIGS. 3H and 3I present the integrated intensity of the characteristic Raman and PL peaks as a function of the illumination intensity, respectively showing that complete conversion is realized with laser intensity >116 mW/μm².

It is noted that, for the optical intensities >230 mW/μm², reduction in all Raman signals was observed. This may be associated with the laser induced sample damage. To avoid such degradation, the present embodiments contemplate laser intensity of about 146 mW/μm² for further analysis and device fabrications, for which no structural damage or conductivity degradation (as reported previously by laser heating on In₂Se₃ nanowire⁴⁴) was observed.

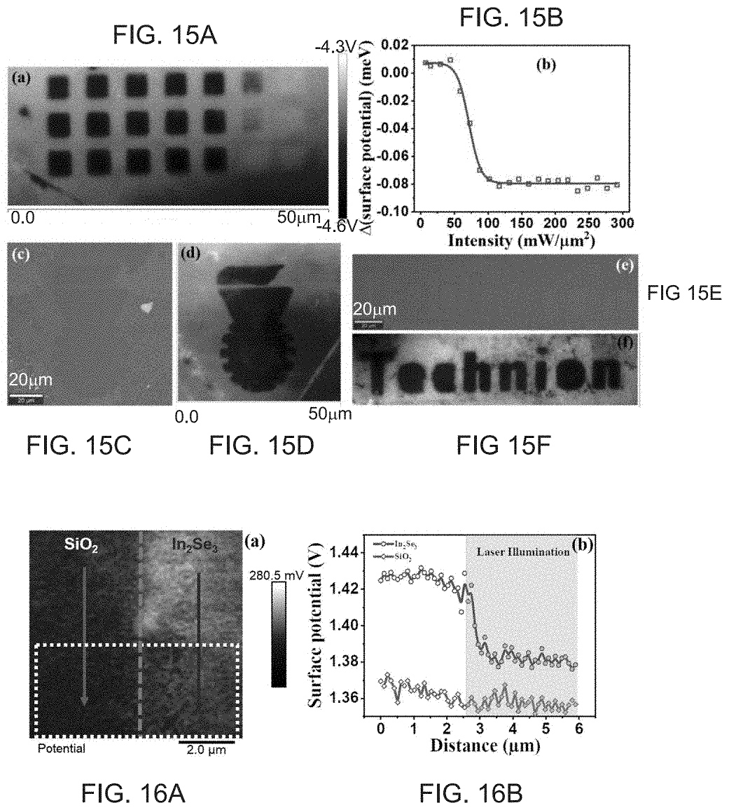

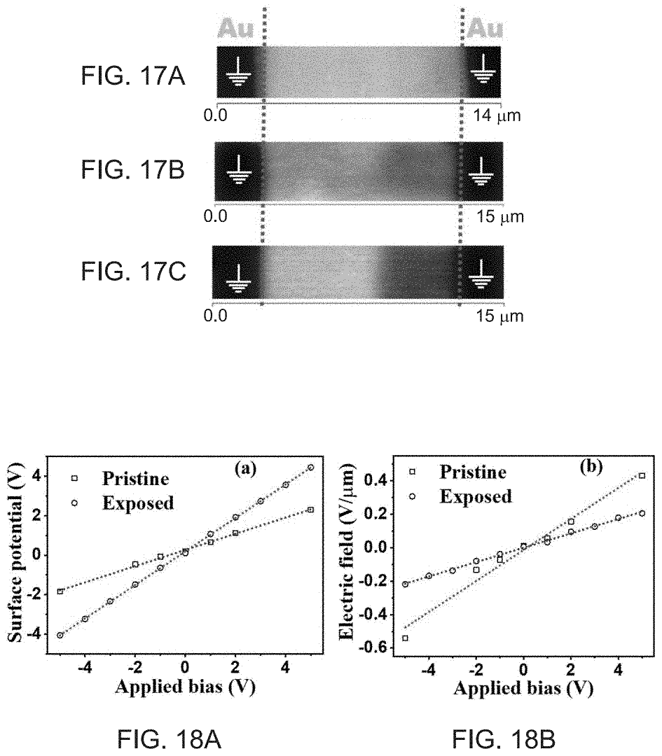

Kelvin probe force microscopy (KPFM)^{45,46} was used to measure the surface potential of the square areas irradiated by various laser intensities (FIGS. 15A-F). Surprisingly, at deficient laser intensities (<43 mW/μm²), the potential becomes higher than the pristine layer, whereas, for higher intensity (>43-102 mW/μm²) the localized potential of the same starts to decrease and saturates thereafter (>102 mW/μm²). To eliminate any probable contributions in measured surface potential from the SiO₂ substrate after laser illumination, the Inventors selectively exposed a section of the In₂Se₃ film and SiO₂ substrate (FIGS. 16A-B). Nevertheless, no potential changes over the SiO₂ part were observed following laser irradiation. In order to study the electronic properties in detail, a systematic comparison of surface potential distribution along FET channels for pristine and laser-irradiated samples have been investigated, as shown in FIGS. 17A-C.

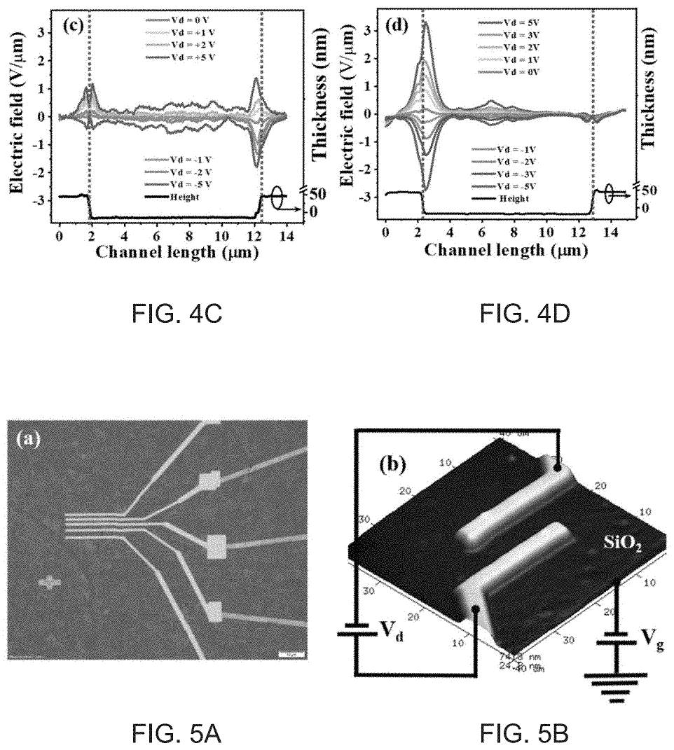

FIGS. 4A and 4B show the surface potential profiles along the channel for variable applied source-drain bias conditions (−5 V to +5 V) for the pristine and laser exposed channel, respectively. The voltage was applied by grounding one contact and biasing the other, while the back-gate electrode was grounded throughout the measurement. A linear electrostatic potential along the biased channel indicates the uniform charge carrier distribution through the In₂Se₃ layers (FIG. 4A).⁴⁷ In contrast, laser irradiated FETs present significantly smaller potential slope, indicating higher conductivity for exposed surfaces. Moreover, the potentials are abruptly changed at the left electrode with diminished drop at the right electrode (on which the voltage is applied) indicating the ohmic nature of the metal-In₂O₃ contacts.⁴⁸

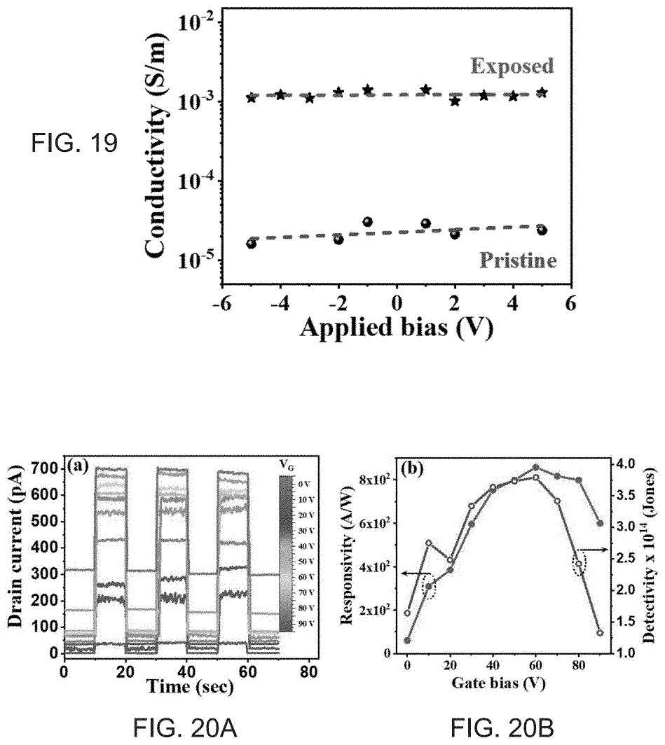

The longitudinal electric field profiles can be calculated by differentiating the measured potential distribution along the FET channels (FIGS. 4C-D). The rapid increase of the electric field at both Au/In₂Se₃ M-S interface for the pristine sample (FIG. 4C) indicates the formation of Schottky barriers which lead to non-ohmic IV characteristics (discussed below). In contrast, for the laser exposed channel, the reduced electric field at the drain M-S junction (4d) indicates the formation of an ohmic junction, leading to linear I_{D}-V_{D} characteristics (discussed below). The current through the FET channel was used to calculate the intrinsic local conductivity of both cases, by using the following equations⁴⁷:

$$σ = \frac{J}{E ( x )} ,$$

where J is the current density and E(x) is the local electric field. It is observed that the channel conductivity is enhanced by two-orders for the converted channel i.e. from 2×10⁻⁵ S/m to 2×10⁻³ S/m (FIG. 19). The electron density (n) was estimated to be ˜1.55*10¹⁶ cm⁻³, and 3.15*10¹⁶ cm⁻³, for pristine In₂Se₃ and converted In₂O₃, respectively. The above data and analysis suggest that FET channels can be tailored to produce parallel arrays of p-n junction FETs by forming In₂Se₃/In₂O₃ heterostructure.

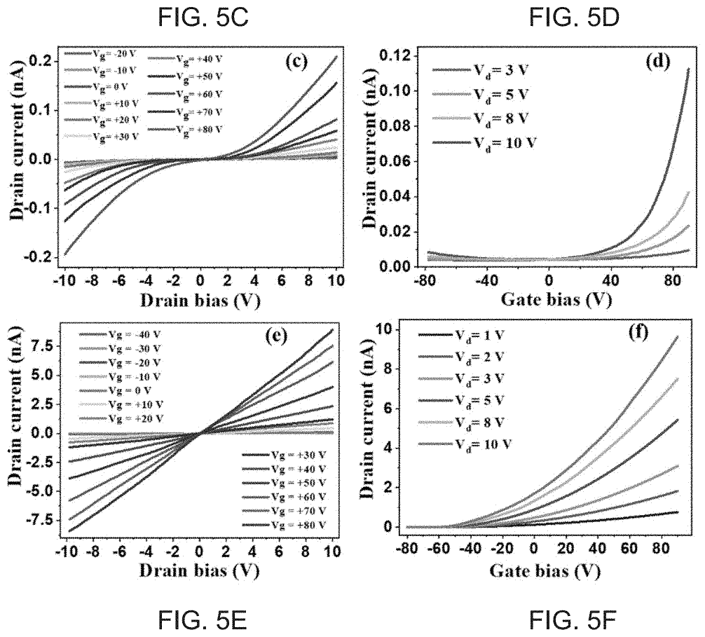

Prior to the multi-channel FET fabrication, the electrical transport properties have been examined for pristine In₂Se₃ and the laser irradiated In₂Se₃ (FIGS. 5A-B). The output (I_{D}-V_{D}) characteristics with varying gate bias (V_{G}) of the fabricated bg-FETs using about 7 nm thick pristine In₂Se₃ are shown in FIG. 5C, whereas the transfer (I_{D}-V_{G}) characteristics for different source-drain bias (V_{D}) of the same device are exhibited in FIG. 5D. The nonlinear output characteristics indicate the presence of tunnelling Schottky barrier at the Au—In₂Se₃ interface and are consistent with the potential mapping. The transfer curves of pristine In₂Se₃ displays typical n-type characteristics with high turn-on voltage (about 50 V). It is to be noted that at very high negative V_{G}, a p-type signature was evolved.

Pristine In₂Se₃ possesses a comparatively smaller bandgap (about 1.4 eV) and, by applying high negative-gate bias, it is possible to move the Fermi level towards the valence band edge, being placed below the mid-gap energy state, which possibly creates p-type In₂Se₃ at high negative V_{G}. The output characteristics for the laser-exposed bg-FET exhibit a linear I_{D}-V_{D} behaviour with increased current by two orders of magnitude due to the formation of ohmic contacts and the material conversion from In₂Se₃ to In₂O₃ (FIG. 5E). The on current (Iₒₙ) of the laser treated device was found to be about 3.5 nA (V_{D}=+5 V, V_{G}=+60 V), which is more than 375 times higher than that of the pristine FET (I_{ON} about 9.3 pA). The field-effect mobility (μ_{F}) of In₂Se₃ FETs was estimated using the following equation,³²

$${μ}_{F} = \frac{\partial {I}_{D}}{\partial {V}_{G}} \times \frac{L}{W \cdot {C}_{o x} \cdot {V}_{D}}$$

where W and L are the channel width and length, respectively and Cₒₓ is the capacitance per unit area of the 300 nm SiO₂ dielectric layer (about 1.15×10⁻⁴ F/m²). The calculated field-effect mobility (μ_{F}) of the pristine and the exposed In₂Se₃ FET devices were about 9.55×10⁻⁵ cm²/V-s and 2.51×10⁻³ cm²/V-s, respectively. Carrier mobility of the exposed device was enhanced by 10² order compared to that of pristine In₂Se₃, suggesting that the channel was nominally n-type and became strongly n-type after light illumination.

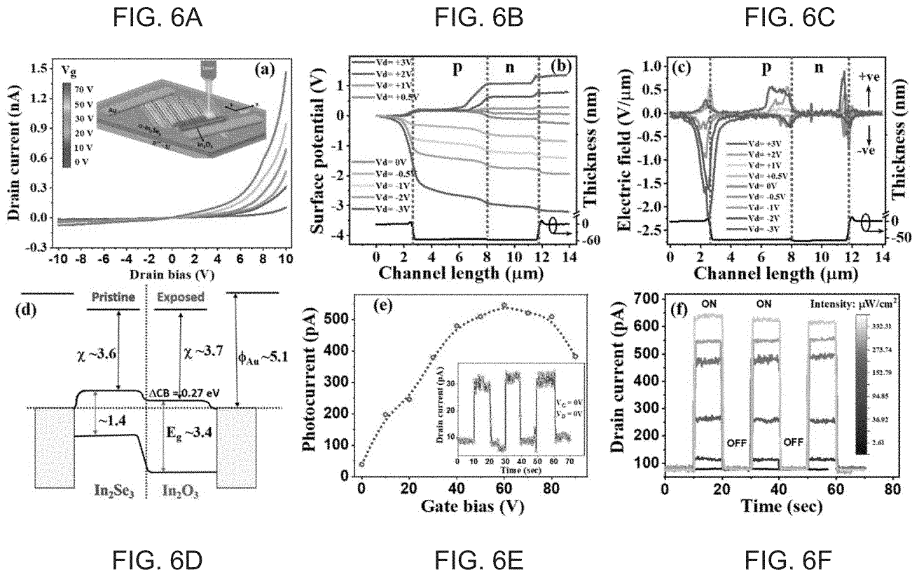

In this Example, arrays of analogous p-n heterojunction FET were directly fabricated on In₂Se₃ layer by selective illumination on the half-width of the channel (inset of FIG. 6A). Room temperature output characteristics of the heterojunction diode for different gate bias, are presented in FIG. 6A. The rectifying behaviour directly indicates the formation of p-n heterojunction channel. The local potential variation across the channel reveals a sharp potential drop at the In₂Se₃—In₂O₃ interface confirms the formation of p-n junction (FIG. 6B). The result highlights the potential to realize lateral heterojunctions, where the two types of materials are not overlapping but rather sharing an atomically sharp 1D junction. The electric field variation along the heterojunction channel is also deduced and displayed in FIG. 6C. By applying positive voltage to the In₂O₃-side, the heterojunction becomes forward biased, and vice-versa, also establishing the n⁺ nature of conversion. It is observed that the depletion widths across the heterojunction are increased with reversed bias, and extended towards the In₂Se₃ layer due to its low carrier concentration.

By considering the bandgap and electron affinity from literature¹² and the measured work-function in this study, a type-II band-alignment was deduced, as displayed in FIG. 6D. Approximate values for valence-band and conduction-band offsets for In₂Se₃—In₂O₃ were found to be Δ_{VB} about 2.27 eV and Δ_{CB} about 0.27 eV, respectively. The substantial barrier for hole transport from In₂Se₃ to In₂O₃ and small barrier for electron transport hinder the photo-carrier recombination, is advantageous for photodetectors or solar cells applications.

The lateral p-n heterojunctions have been utilized for photodetection. The photo-response of the device at room temperature for different gate bias was examined (FIGS. 20A-B) and the calculated photocurrent (I_{Photo}=I_{light}−I_{dark}) peak was found at an applied gate bias of about 60V (FIG. 6E). Advantageously, the device exhibits photo-response even without applying any external bias upon periodic illumination of white light, owing to its in-built potential due to band-offset (inset of FIG. 6E), thus becomes attractive as a self-powered, portable photodetector. The fabricated p-n junction did not exhibit considerable photovoltage, which can be explained due to the fact that both pristine In₂Se₃ and In₂O₃ comprise electrons as majority carrier, forming considerably lower built-in potential than in conventional p-n junction.

The photocurrent response over time for different illumination intensities were also tested (at V_{G}=60 V) and depicted in FIG. 6F. Upon illumination, the device current rises and stabilizes (ON state) and switches back to the initial level (OFF state) for dark condition, demonstrating a stable and repetitive photo-response. The device generates photocurrent even at a very low illumination intensity down to about 3 μW/cm².

Photoresponsivity (R)⁴⁹ and detectivity (D)⁵⁰ were extracted (see ESI, FIG. 15B), and the peak values are found to be about 857 A/W, and 3.8×10¹⁴ Jones respectively, for the +60 V gate bias. Note that the high photo response observed at a positive applied gate voltage of about 60V is counterintuitive due to the higher expected drift current attributed to higher electron concentration. The Inventors attribute this behaviour to the induced in-plane polarization in the ferroelectric In₂Se₃, which can effectively increase the amount of collected charge and the measured photocurrent. The ultrahigh photo-detectivity is two orders of magnitude higher than the similar multilayer-based photo-transistor and the highest for In₂Se₃. The photocurrent generation mechanism may rely on a combination of several process, such as, photoconduction, e-h pair generation in junction's depletion width, photo-thermo-electric effect etc. In the experiments reported in this Example, the employed illumination spot was much larger than the actual device area, and therefore one does not expect any sharp thermal gradients, which is responsible for thermal mechanisms to the total photocurrent. Therefore, the Inventors ruled out the presence of photo-thermoelectric effect.

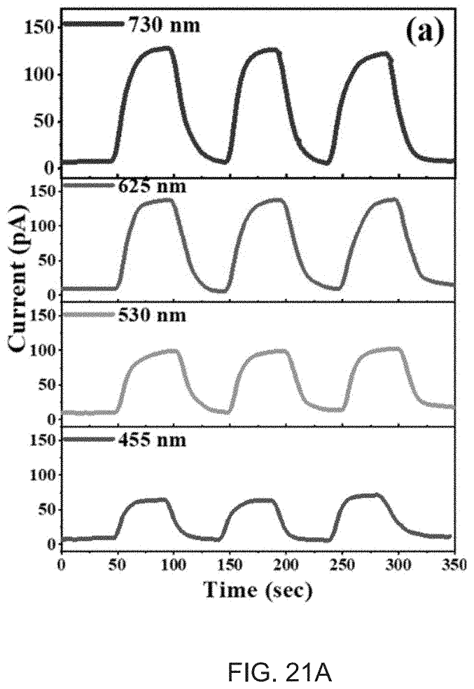

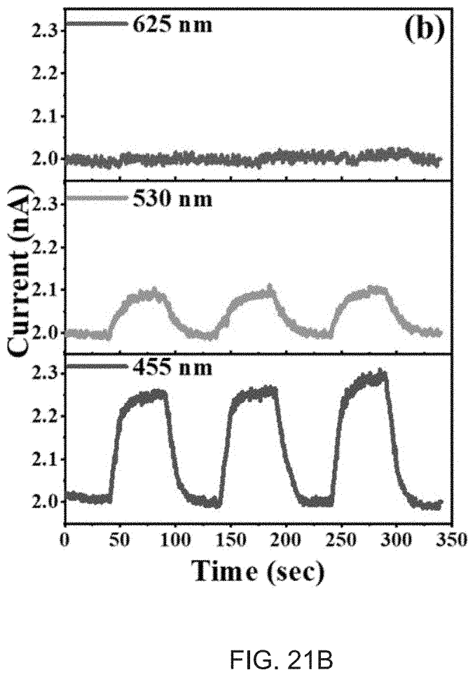

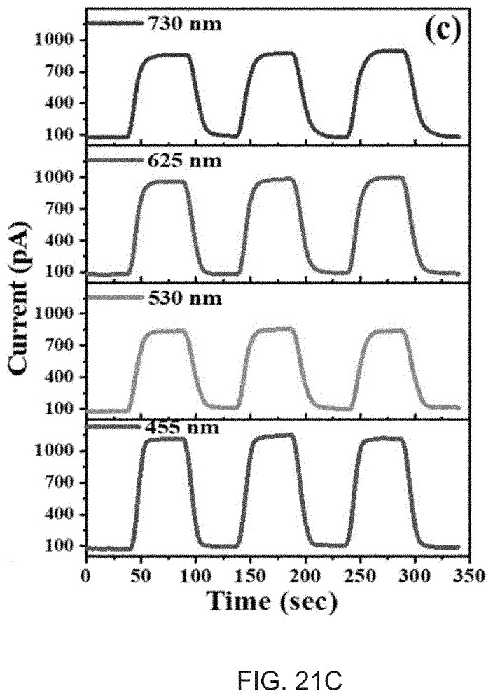

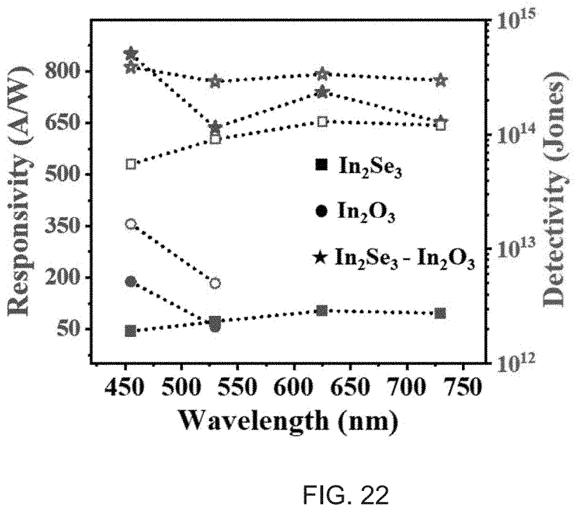

To disentangle the underlaying photo-generation mechanism in the fabricated p-n junction, the Inventors further performed the photosensitivity test for four different excitation (blue, green, red and infrared) wavelengths for three separate FETs: 1) p-n junction, 2) In₂Se₃ and 3) In₂O₃. The results are depicted in FIGS. 21A-C and 22. For the In₂Se₃ a broad-spectral response was observed over the visible wavelength regime, which is in excellent agreement with available literature.^{7,51} It has been suggested that the native surface oxide of the In₂Se₃ flakes in ambient conditions acts as an efficient absorber and energy converter for blue and green light, which supports this broad response. However, for In₂O₃ layers, discernible photocurrent was only observed for blue and green excitation, attributed to the near band-edge and oxide defects present in the materials, respectively. Additionally, the photogenerated holes are trapped at the oxide interface, resulting in high photo-gain and slow response times, as often observed in In₂Se₃ photodetectors.^{7,51} The control experiments indicate that the photo-conduction mechanism is present in both In₂Se₃ and In₂O₃ layers. It is noted that boosted (about 15 times) photoresponse over the entire visible wavelength range is observed for the heterojunction sample, under same measurement conditions.

The diversity of the band-structure in the heterojunction devices, from a narrow-gap (˜1.4 eV) to a wide-gap (˜3.4 eV) helps to absorb entire visible wavelengths, resulting in broadband photodetection. The presence of a distinct energy barrier at the In₂Se₃/In₂O₃ junction as revealed by KPFM measurements, creates a local charge depletion layer resulting in the formation of interfacial built-in electric field, as expected from the band discontinuity between In₂Se₃ and In₂O₃. This interfacial built-in electric field separates photogenerated electrons and holes from the depletion region and helps to collect charge carriers by the respective electrodes, leading to the zero-bias photocurrent. Therefore, by applying a negative bias, the photocurrent becomes further increased, as the depletion width increases (revealed by bias dependent KPFM) and exhibits boosted (about 15 times) photoresponse for the heterojunction device as compared to the pristine In₂Se₃ and In₂O₃.

### Conclusions

This Example demonstrated a post-synthesis nanofabrication technique for realizing scalable integration of coplanar heterojunction monolithic devices on 2D In₂Se₃. A focused visible laser beam is selectively used to pattern In₂Se₃ layers, where the exposed locations are converted to In₂O₃. The atomically thin In₂O₃ layers exhibit two orders of magnitude enhancement of conductivity and mobility, and the metal-semiconductor interfaces transformed from Schottky to ohmic, which is essential for high-end opto-electronics. Fabricated heterojunction phototransistors exhibit superior photodetection characteristics i.e. responsivity about 857 A/W and detectivity about 3.8×10¹⁴ Jones. The method demonstrated enables the development of versatile in-plane 2D heterojunction devices for wafer-scale integrated electronics and optoelectronics applications.

### Methods

Growth of In₂Se₃ Nanolayers

Large-area few-layer In₂Se₃ was grown on mica substrate in a CVD system equipped with a 1-inch diameter quartz tube (FIG. 7A). High purity Se (99.95%, Sigma Aldrich) and In₂O₃ (99.998%, Sigma Aldrich) powders were used as the growth precursor. In essence, 100 mg of In₂O₃ powder was placed in a ceramic boat at the centre of the tube furnace. A freshly cleaved mica piece (SPI Phlogopite Mica) served as the growth substrate was placed downstream (about 1 cm) to the In₂O₃ powder. Another ceramic boat containing Se powder (50 mg) was kept 17 cm away from the In₂O₃ boat (upstream). The furnace was purged with high flow (300 sccm) of 5N Ar for 15 minutes prior to growth process. It was then heated to 150° C. in 10 minutes and wait for another 10 minutes with the same high flow of Ar, to remove any unwanted contamination present inside the quartz tube. The furnace was then heated to 630° C. (rate about 15° C./min) with 50 sccm of Ar and 5 sccm of H₂ flow. Se powder was maintained at 250° C. with external heating tape when the temperature of the furnace reaches about 630° C.

The furnace was maintained at 630° C. for a time period varying from 5 minutes to 1 hr for the growth depending on the desired film thickness. After the growth, the furnace was allowed to cool naturally until it reached the room temperature. FIG. 7B exhibits the optical image of few-layers of In₂Se₃ on mica, whereas, FIG. 7C shows the same on a SiO₂ substrate after the wet-transfer process. The deep bluish region represents the In₂Se₃ having a homogeneous contrast, while the purple background is 300 nm SiO₂ on Si.

Transfer Methodology

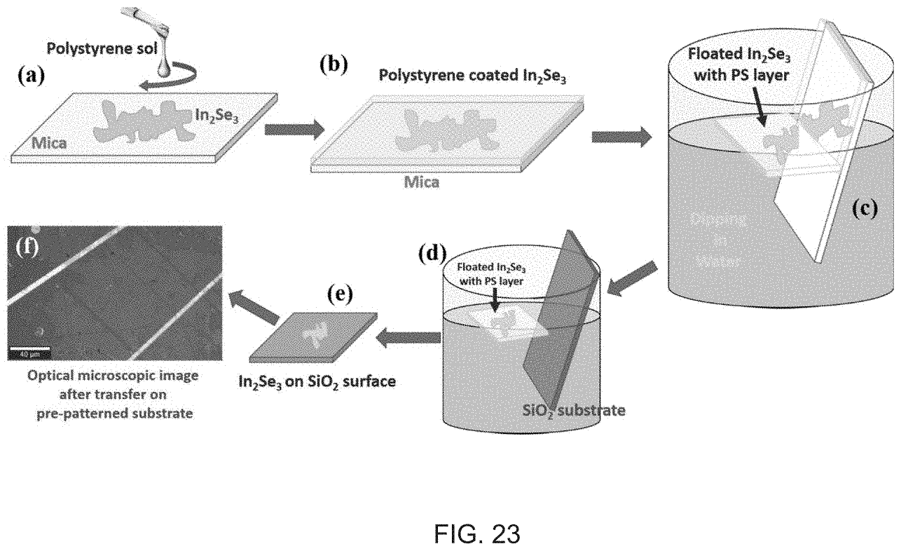

The Inventors followed surface energy-assisted wet-transfer technique using polystyrene (PS) film to transfer the In₂Se₃ samples onto a pre-patterned substrate as reported elsewhere.⁵² FIG. 23 schematically illustrates the experimental procedure to transfer the as-grown In₂Se₃ layers from mica to the desired substrate. In a typical process, 450 mg of PS (280000 g/mol) was added to 5 ml of toluene and stirred well until dissolved. A layer of PS was spin-coated (5 seconds at 500 rpm and 60 seconds at 3500 rpm) onto as-grown In₂Se₃ on a mica substrate. Thereafter, the assembly was baked at 90° C. for 30 minutes, followed by further baking at 120° C. for 10 minutes for proper adherence of PS film to In₂Se₃. The assembly was scooped off instantly after the water penetrates inside the gap between the PS film and the substrate (mica). The detached polymer/In₂Se₃ assembly was then fished onto a freshly cleaned SiO₂/Si substrate where the metal fingers are pre-defined by photolithography and e-beam evaporation, and left for drying in ambient condition.

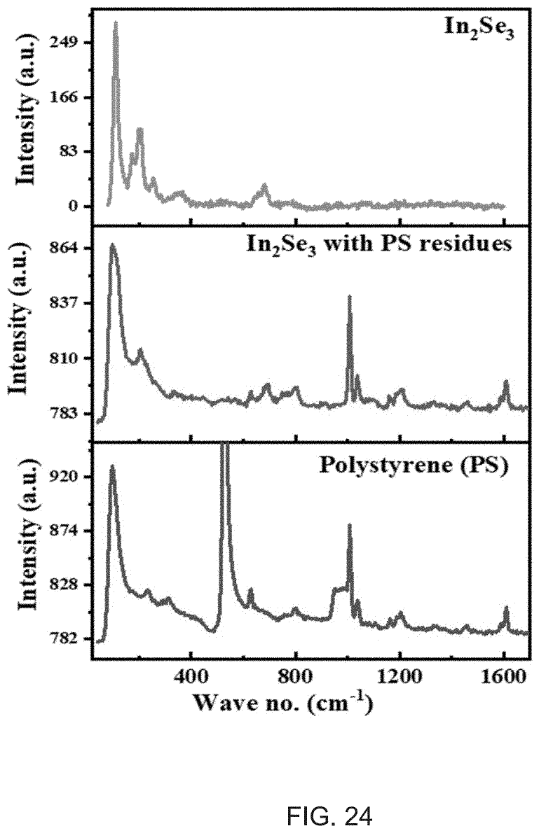

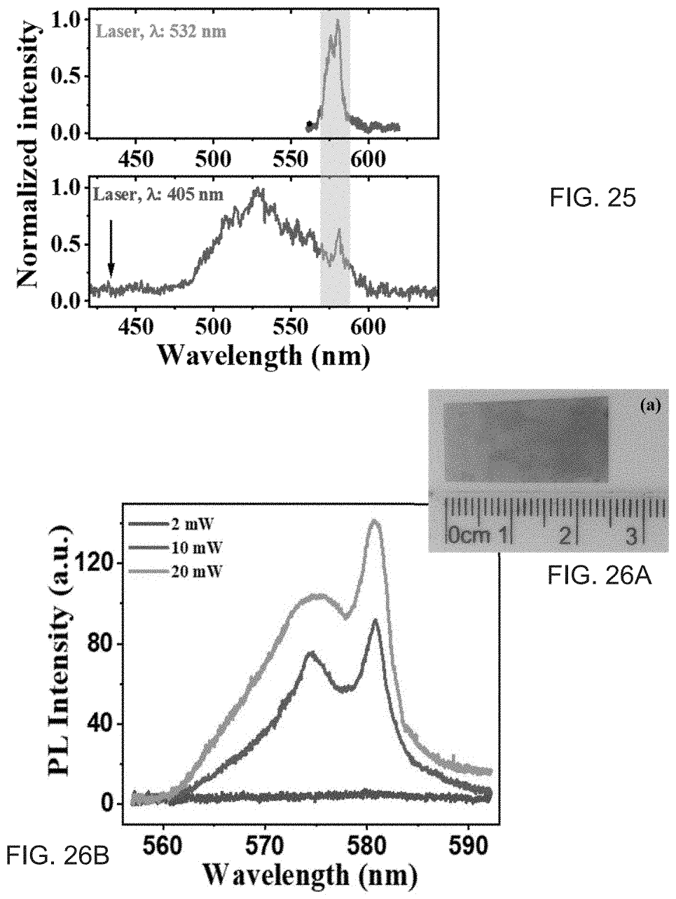

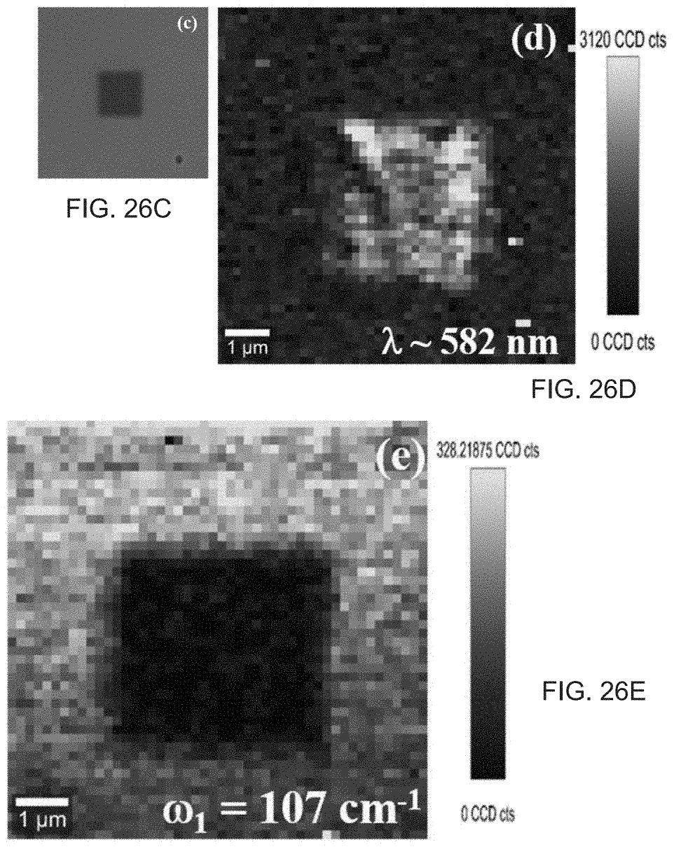

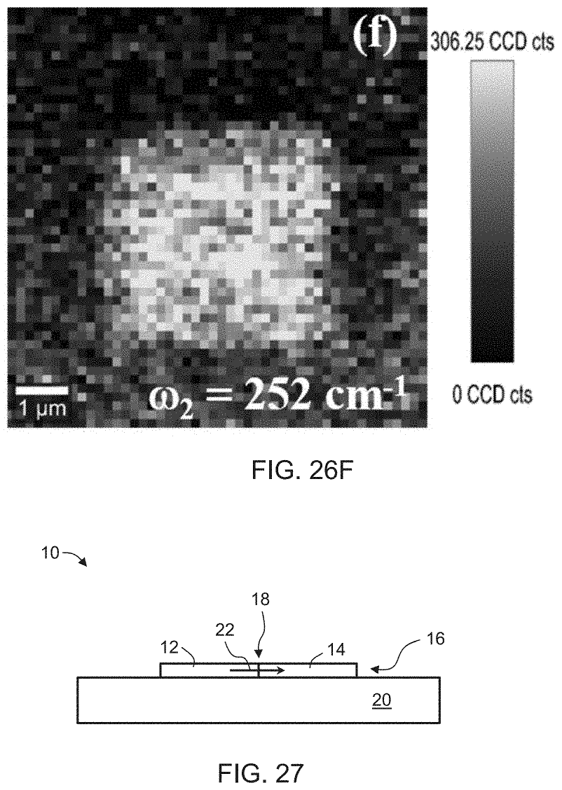

To remove any water residue, the transferred assembly was baked on a hot plate at 90° C. for 30 minutes and further to 120° C. for 15 minutes to avoid any possible wrinkle formation. Finally, the PS layer was removed by dissolving in toluene. Comparative Raman spectra for polystyrene (PS) film, In₂Se₃ with PS residues and the In₂Se₃ after PS removal on SiO₂ substrate were exhibited to confirm the quality of the transferred flakes (FIG. 24). To ensure that the measured PL spectra of the exposed samples can be attributed to the presence of In₂O₃ and not to carbon based residues from the PS polymer, PL spectra of exposed In₂Se₃ layers before transfer (on mica) and using 405 nm laser excitation is included in the SI section (FIGS. 25 and 26A-F).

Characterizations

Structural Characterizations

The sample morphology was investigated based on atomic force microscopy (AFM) by employing a Bruker Dimension-ScanAsyst instrument. High-resolution (HR) TEM imaging and elemental distribution mapping were recorded using a double Cs-corrected HR-S/TEM, Titan Themis G² 60-300 [FEI/Thermo Fisher, USA], equipped with a Dual-X detector [Bruker corporation, USA] EDS probe. The EDS maps were acquired, post-processed and analyzed using the Velox software [Thermo-Fisher, USA]. The TEM samples were prepared by transferring the CVD-grown In₂Se₃ layers onto Cu-TEM grid by the wet-transfer method stated above. Then, the pristine In₂Se₃ samples were selectively exposed by focused laser illumination with variable powers in atmospheric conditions. The samples were treated by mild Ar/H₂ [80:20] plasma for 10 sec [1020 plasma cleaner, Fishione, USA] before performing the microscopy experiment.

Spectroscopic Characterization

TOF-SIMS analysis was carried out using a dual ion-beam TOF-SIMA V unit [IONTOF GmbH, Germany] equipped with liquid bismuth metal ion probe for detection and Cs/O₂ ion gun for sputtering. The energy of Bi⁺ ions was fixed at 25 keV during the measurement, and the analyzer was set to measure the negative ions. For sputtering Cs⁺ ions were used with 1 keV energy, and the sputter rate was kept as low as 0.0544 nm/sec. PL and Raman spectra were recorded using a WITec Alpha300R Raman Microscope setup in confocal mode comprising of an Ar laser (λ=532.5 nm), an optical confocal microscope system, a spectrometer and a motor controlled XY positioning stage. A typical 100× objective (NA=0.9; Δλ about 360 nm) was used to focus the laser beam, while the laser power was typically kept fixed at about 1 mW for the PL and Raman measurements to avoid material degradation. To achieve the position-controlled patterns and optimize the threshold power required for conversion process, In₂Se₃ nanosheets were selectively exposed in the confocal Raman set-up using 100× objective (NA=0.9; Δλ about 360 nm) to focus the 532.5 nm laser and, by varying laser powers starting from as low as 7.28 mW/μm² to 291.4 mW/μm² using 2.5 microns/sec scan speed of the laser probe. The diffraction limited illuminated area of the laser spot was estimated to be about 0.10 μm². The materials conversion experiment was performed at room temperature and in open air, under atmospheric conditions.

Device Fabrication and Electrical Measurements

The sample was first transferred onto a pre-patterned 300 nm SiO₂/p⁺⁺-Si substrate through the wet-transfer technique mentioned earlier. Standard electron beam lithography [Raith-eLine] was employed to define contact pads. Prior to metal evaporation, a mild oxygen plasma of 50 W for about 5 seconds was used to remove the unwarranted resist residuals. 5/50 nm of Cr/Au was subsequently deposited onto the surface by electron beam evaporation [Evatec BAK 501A] to serve as electrodes. The deposition rate was minimized down to about 0.5 Å/s for Cr and to about 1 Å/s for Au at the base pressure of about 7×10⁻⁷ torr. Kelvin probe force microscopy was carried out inside an N₂ filled glovebox (H₂O and O₂ vapor content <1 ppm) using amplitude modulation (AM-KPFM) technique (Dimension-Scanassist, Bruker Inc.). Pt/Ir-coated n⁺-Silicon cantilevers [PPP-EFM-50, NANOSENSORS™] with about 25 nm apex diameter were used for the potential mapping. Beforehand, the devices were mounted onto a chip carrier followed by wire bonding to make complete prototype device fabrication.

The electrical measurements of FET devices were carried out using a semiconductor parameter analyzer (Keysight B1500A) and a probe station equipped with an optical microscope. For the FETs, the V_{G} was applied through back-side conducting (p⁺⁺) Si and the 300-nm-thick SiO₂ layer served as the gate dielectric. The in-plane p-n heterojunction was realized by partially illuminating the FET channels between source and drain by using the 532 nm laser with about 151.8 mW/μm². The photoconductivity study was carried out under white LED light focused through the microscope having the intensity range from about 3 μW/cm² to 332 μW/cm², and the photocurrent signal was measured.

Following are: schematic of growth set-up and 2D layer transfer; Raman spectra for PS coated and PS removed In₂Se₃; optical images, HR-TEM and Raman map of In₂Se₃; PL and Raman map on mica substrate, schematic of materials conversion; KPFM potential map for laser intensity calibration; potential map, electric field and conductivity of FETs; responsivity & detectivity calculations and plots with gate bias.

To find the effect of time period of laser irradiation on the sample, the Inventors performed a control experiment for different intensities and exposure times, while maintaining the same optical dose, for fair comparisons. The optical dose is defined as:

$$Optical dose , D ( \frac{m J}{{cm}^{2}} ) = \frac{incident power * exposure time}{illuminated area} ( \frac{mW * sec}{{cm}^{2}} ) \qquad ( 1 )$$

The optical image for various exposure periods and powers is presented in FIG. 9A. Corresponding optical dose is written above each column. Raman maps for the characteristic vibrational modes (about 107 cm⁻¹ and 253 cm⁻¹) obtained are depicted in FIGS. 9B-C, respectively.

It is observed that for low power and short time exposures there is almost no effect on In₂Se₃, indicates negligible photo-induced local temperature change. However, for high powers one can see a distinct change, even for a very short pulse. For low optical power, and prolonged exposure, materials' conversion and broadening of the exposed area (square boxes) was observed. This indicates that the heat dissipation mostly takes place at the cross-plane direction and has strong time-dependent thermal anisotropy for heat conduction, which is typical for 2D materials. The material's conversion mechanism is schematically illustrated in FIG. 10. Previous studies suggest that the local laser heating can weaken certain atomic bonds and destabilize the crystal lattice [40]. Therefore, the heat dissipation in the material is an important factor which can significantly increase the local temperature and can lead to the larger-than-diffraction-limited laser profile of actual exposed region. Moreover, high absorption coefficient of In₂Se₃ (about 10⁵ cm⁻¹) results in significant absorption of light, and high thermal anisotropy leading to strong local heating [53]. The rate of thermal transport away from an optically heated surface depends strongly on the thermal conductivity of the material [54]. It is noted that the effect of domain-boundary scattering, presence of grain boundaries and phonon impurities in the CVD grown films combinedly lead to the poor heat dissipation, resulting in significant local temperature increment.

To better understand the transient evolution of the surface temperature and heat dissipation in the experiment reported in this Example, a finite element method (FEM) based thermal simulation model using COMSOL Multiphysics software package is presented. The model provides the time dependent laser-induced estimated local temperature rise in In₂Se₃ on SiO₂/Si substrate for different values of incident power. The heat diffusion equation was solved by considering a Gaussian-shaped laser beam as the heat source. The thickness of In₂Se₃ and SiO₂ layer were reserved as 10 nm and 300 nm respectively to replicate the actual device structure. The layer-thickness dependent thermal conductivity, absorption coefficient and reflection coefficient were taken from literature [55]. The average simulated temperature (T_{S}) due to the laser heating was obtained using equation,

$${T}_{s} = \frac{{{\int }^{r}}_{0} {T}^{′} ( r ) Q ( r ) rdr}{{{\int }^{r}}_{0} Q ( r ) rdr} \qquad ( 2 )$$

where T′(r) is the local temperature rise for laser heating as a function of distance r from the center of laser spot. Q(r) represents the volumetric Gaussian laser heat source, and can be described as,

$$Q ( r ) = \frac{{P}_{a b}}{π {r}_{0}^{2}} {e}^{- ( \frac{{r}^{2}}{{r}_{0}^{2}} )} \cdot {e}^{- α \vert d \vert} \qquad ( 3 )$$

where P_{ab} is the absorbed laser power, d is the layer thickness, and r₀ is the beam width. The absorbed laser power can be written as, P_{ab}=(1−R)αP₀, where P₀ is the incident laser power, R and α are the In₂Se₃ reflection and absorption coefficients, respectively.

The time-dependent heat transfer was solved using the following equation:

$$ρ {C}_{s p} ( \frac{\partial T}{δ t} + {V}_{t r} \cdot ∇ T ) + ∇ \cdot ( {q}_{c} + {q}_{r} ) = {Q}_{i n} \qquad ( 4 )$$

where, ρ, Cₛₚ and α_{Th} are the density, specific heat capacity and thermal expansion coefficient of the materials, respectively; T is the temperature; q_{c} and qᵣ are the heat flux by conduction and radiation; Qᵢₙ is the heat source for laser illumination.

A simulated surface temperature distribution is shown in FIG. 11A with a planner projection (FIG. 11B). The time-dependent local temperature rise for two laser powers are exhibited in FIGS. 11C-D. For the high laser intensity, the temperature rapidly rises and can initiate the material's conversion process, but for low intensity, one required much longer timescale to reach that temperature. The time-dependent nonlinear heating predicted by the model for longer time scale is mostly dominated by in-plane heat flow and saturates as the system reaches thermal equilibrium. It is reported that at high temperatures the specific heat is expected to saturate, which might be the reason for saturation of the local temperature rise with time, showing good agreement with the experimental data. In a nutshell, a smaller laser power for longer exposure time allows better heat dissipation in the lateral directions, identified as overdose for the desired structure (square boxes in FIGS. 9A-C). However, low-power and low exposure time indicates negligible optical heating, suggesting under dose for the patterning. Therefore, moderate power (>5-6 mW) and low-exposure time is optimum to engineer in-plane heterostructure devices.

The responsivity of a photodetector device can be calculated using the following equation [49],

$$( λ ) = \frac{{J}_{P h o t o} ( λ )}{{P}_{d}} \qquad ( 5 )$$

Where, J_{Photo} is the photocurrent density and P_{d} is the incident power density.

Detectivity (D*), which is another important parameter of a photodetector, represents the ability to detect weak optical signals from noisy background and can be expressed as [50],

$${D}^{*} = \frac{( λ )}{\sqrt{q \cdot {J}_{dark}}} \qquad ( 6 )$$

Where, J_{dark} is the dark current density and q is the electronic charge.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

It is the intent of the applicant(s) that all publications, patents and patent applications referred to in this specification are to be incorporated in their entirety by reference into the specification, as if each individual publication, patent or patent application was specifically and individually noted when referenced that it is to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

### REFERENCES

(1) Das, S.; Gulotty, R.; Sumant, A. V.; Roelofs, A. All Two-Dimensional, Flexible, Transparent, and Thinnest Thin Film Transistor. Nano Lett. 2014, 14 (5), 2861-2866.
(2) Li, L.; Yu, Y.; Ye, G. J.; Ge, Q.; Ou, X.; Wu, H.; Feng, D.; Chen, X. H.; Zhang, Y. Black Phosphorus Field-Effect Transistors. Nat. Nanotechnol. 2014, 9 (5), 372-377.
(3) Cui, C.; Xue, F.; Hu, W. J.; Li, L. J. Two-Dimensional Materials with Piezoelectric and Ferroelectric Functionalities. npj 2D Mater. Appl. 2018, 2 (1), 1-14.
(4) Jana, S.; Mukherjee, S.; Ghorai, A.; Bhaktha, S. B. N.; Ray, S. K. Negative Thermal Quenching and Size-Dependent Optical Characteristics of Highly Luminescent Phosphorene Nanocrystals. Adv. Opt. Mater. 2020, 8 (12), 2000180.
(5) Mukherjee, S.; Maiti, R.; Midya, A.; Das, S.; Ray, S. K. Tunable Direct Bandgap Optical Transitions in MoS₂ Nanocrystals for Photonic Devices. ACS Photonics 2015, 2 (6), 760-768.
(6) Zhou, J.; Zeng, Q.; Lv, D.; Sun, L.; Niu, L.; Fu, W.; Liu, F.; Shen, Z.; Jin, C.; Liu, Z. Controlled Synthesis of High-Quality Monolayered α-In₂Se₃ via Physical Vapor Deposition. Nano Lett. 2015, 15 (10), 6400-6405.
(7) Island, J. O.; Blanter, S. I.; Buscema, M.; van der Zant, H. S. J.; Castellanos-Gomez, A. Gate Controlled Photocurrent Generation Mechanisms in High-Gain In₂Se₃ Phototransistors. Nano Lett. 2015, 15 (12), 7853-7858.
(8) Cui, C.; Hu, W. J.; Yan, X.; Addiego, C.; Gao, W.; Wang, Y.; Wang, Z.; Li, L.; Cheng, Y.; Li, P.; Zhang, X.; Alshareef, H. N.; Wu, T.; Zhu, W.; Pan, X.; Li, L. J. Intercorrelated In-Plane and Out-of-Plane Ferroelectricity in Ultrathin Two-Dimensional Layered Semiconductor In₂Se₃. Nano Lett. 2018, 18 (2), 1253-1258.
(9) Poh, S. M.; Tan, S. J. R.; Wang, H.; Song, P.; Abidi, I. H.; Zhao, X.; Dan, J.; Chen, J.; Luo, Z.; Pennycook, S. J.; Castro Neto, A. H.; Loh, K. P. Molecular-Beam Epitaxy of Two-Dimensional In₂Se₃ and Its Giant Electroresistance Switching in Ferroresistive Memory Junction. Nano Lett. 2018, 18 (10), 6340-6346.
(10) Almeida, G.; Dogan, S.; Bertoni, G.; Giannini, C.; Gaspari, R.; Perissinotto, S.; Krahne, R.; Ghosh, S.; Manna, L. Colloidal Monolayer β-In₂Se₃ Nanosheets with High Photoresponsivity. J. Am. Chem. Soc. 2017, 139 (8), 3005-3011.
(11) Shen, G.; Xu, J.; Wang, X.; Huang, H.; Chen, D. Growth of Directly Transferable In₂O₃ Nanowire Mats for Transparent Thin-Film Transistor Applications. Adv. Mater. 2011, 23 (6), 771-775.
(12) Huang, B.; Zhang, Z.; Zhao, C.; Cairang, L.; Bai, J.; Zhang, Y.; Mu, X.; Du, J.; Wang, H.; Pan, X.; Zhou, J.; Xie, E. Enhanced Gas-Sensing Performance of ZnO@In₂O₃ Core@shell Nanofibers Prepared by Coaxial Electrospinning. Sens. Actuators, B 2018, 255, 2248-2257.
(13) Oxide Materials at the Two-Dimensional Limit; Netzer, F. P., Fortunelli, A., Eds.; Springer Series in Materials Science; Springer International Publishing, 2016. www(dot)doi(dot)org/10(dot)1007/978-3-319-28332-6.
(14) Yang, J.; Zeng, Z.; Kang, J.; Betzler, S.; Czarnik, C.; Zhang, X.; Ophus, C.; Yu, C.; Bustillo, K.; Pan, M.; Qiu, J.; Wang, L. W.; Zheng, H. Formation of Two-Dimensional Transition Metal Oxide Nanosheets with Nanoparticles as Intermediates. Nat. Mater. 2019, 18 (9), 970-976.
(15) Yang, T.; Song, T. T.; Callsen, M.; Zhou, J.; Chai, J. W.; Feng, Y. P.; Wang, S. J.; Yang, M. Atomically Thin 2D Transition Metal Oxides: Structural Reconstruction, Interaction with Substrates, and Potential Applications. Adv. Mater. Interfaces 2019, 6 (1), 1801160.
(16) Novoselov, K. S.; Mishchenko, A.; Carvalho, A.; Castro Neto, A. H. 2D Materials and van Der Waals Heterostructures. Science 2016, 353 (6298).
(17) Wang, X.; Xia, F. Stacked 2D Materials Shed Light. Nat. Mater. 2015, 14 (3), 264-265.
(18) Lyu, J.; Pei, J.; Guo, Y.; Gong, J.; Li, H. A New Opportunity for 2D van Der Waals Heterostructures: Making Steep-Slope Transistors. Adv. Mater. 2020, 32 (2), 1906000.
(19) Jariwala, D.; Marks, T. J.; Hersam, M. C. Mixed-Dimensional van Der Waals Heterostructures. Nat. Mater. 2017, 16 (2), 170-181.
(20) Li, M. Y.; Chen, C. H.; Shi, Y.; Li, L. J. Heterostructures Based on Two-Dimensional Layered Materials and Their Potential Applications. Mater. Today 2016, 19 (6), 322-335.
(21) Li, M. Y.; Shi, Y.; Cheng, C. C.; Lu, L. S.; Lin, Y. C.; Tang, H. L.; Tsai, M. L.; Chu, C. W.; Wei, K. H.; He, J. H.; Chang, W. H.; Suenaga, K.; Li, L. J. Epitaxial Growth of a Monolayer WSe₂—MoS₂ Lateral p-n Junction with an Atomically Sharp Interface. Science 2015, 349 (6247), 524-528.
(22) Liu, L.; Park, J.; Siegel, D. A.; McCarty, K. F.; Clark, K. W.; Deng, W.; Basile, L.; Idrobo, J. C.; Li, A.-P.; Gu, G. Heteroepitaxial Growth of Two-Dimensional Hexagonal Boron Nitride Templated by Graphene Edges. Science 2014, 343 (6167), 163-167.
(23) Yun, T.; Jin, H. M.; Kim, D.-H.; Han, K. H.; Yang, G. G.; Lee, G. Y.; Lee, G. S.; Choi, J. Y.; Kim, I.-D.; Kim, S. O. 2D Metal Chalcogenide Nanopatterns by Block Copolymer Lithography. Adv. Funct. Mater. 2018, 28 (50), 1804508.
(24) Stanford, M. G.; Pudasaini, P. R.; Belianinov, A.; Cross, N.; Noh, J. H.; Koehler, M. R.; Mandrus, D. G.; Duscher, G.; Rondinone, A. J.; Ivanov, I. N.; Ward, T. Z.; Rack, P. D. Focused Helium-Ion Beam Irradiation Effects on Electrical Transport Properties of Few-Layer WSe₂: Enabling Nanoscale Direct Write Homo-Junctions. Sci. Rep. 2016, 6 (1), 27276.
(25) Ghorbani-Asl, M.; Kretschmer, S.; Spearot, D. E.; Krasheninnikov, A. V. Two-Dimensional MoS₂ under Ion Irradiation: From Controlled Defect Production to Electronic Structure Engineering. 2D Mater. 2017, 4 (2), 025078.
(26) Liu, X.; Chen, K. S.; Wells, S. A.; Balla, I.; Zhu, J.; Wood, J. D.; Hersam, M. C. Scanning Probe Nanopatterning and Layer-by-Layer Thinning of Black Phosphorus. Adv. Mater. 2017, 29 (1), 1604121.
(27) Chen, S.; Kim, S.; Chen, W.; Yuan, J.; Bashir, R.; Lou, J.; van der Zande, A. M.; King, W. P. Monolayer MoS₂ Nanoribbon Transistors Fabricated by Scanning Probe Lithography. Nano Lett. 2019, 19 (3), 2092-2098.
(28) Gong, Y.; Yuan, H.; Wu, C. L.; Tang, P.; Yang, S. Z.; Yang, A.; Li, G.; Liu, B.; van de Groep, J.; Brongersma, M. L.; Chisholm, M. F.; Zhang, S. C.; Zhou, W.; Cui, Y. Spatially Controlled Doping of Two-Dimensional SnS₂ through Intercalation for Electronics. Nat. Nanotechnol. 2018, 13 (4), 294-299.
(29) Ouk Kim, S.; Solak, H. H.; Stoykovich, M. P.; Ferrier, N. J.; de Pablo, J. J.; Nealey, P. F. Epitaxial Self-Assembly of Block Copolymers on Lithographically Defined Nanopatterned Substrates. Nature 2003, 424 (6947), 411-414.
(30) Jadwiszczak, J.; O'Callaghan, C.; Zhou, Y.; Fox, D. S.; Weitz, E.; Keane, D.; Cullen, C. P.; O'Reilly, I.; Downing, C.; Shmeliov, A.; Maguire, P.; Gough, J. J.; McGuinness, C.; Ferreira, M. S.; Bradley, A. L.; Boland, J. J.; Duesberg, G. S.; Nicolosi, V.; Zhang, H. Oxide-Mediated Recovery of Field-Effect Mobility in Plasma-Treated MoS₂. Sci. Adv. 2018, 4 (3), eaao5031.
(31) Balakrishnan, N.; Kudrynskyi, Z. R.; Smith, E. F.; Fay, M. W.; Makarovsky, O.; Kovalyuk, Z. D.; Eaves, L.; Beton, P. H.; Patanè, A. Engineering p-n Junctions and Bandgap Tuning of InSe Nanolayers by Controlled Oxidation. 2D Mater. 2017, 4 (2), 025043.
(32) Kappera, R.; Voiry, D.; Yalcin, S. E.; Branch, B.; Gupta, G.; Mohite, A. D.; Chhowalla, M. Phase-Engineered Low-Resistance Contacts for Ultrathin MoS₂ Transistors. Nat. Mater. 2014, 13 (12), 1128-1134.
(33) Cho, S.; Kim, S.; Kim, J. H.; Zhao, J.; Seok, J.; Keum, D. H.; Baik, J.; Choe, D. H.; Chang, K. J.; Suenaga, K.; Kim, S. W.; Lee, Y. H.; Yang, H. Phase Patterning for Ohmic Homojunction Contact in MoTe₂. Science 2015, 349 (6248), 625-628.
(34) Wang, J.; Liu, C. Y.; Senftle, T. P.; Zhu, J.; Zhang, G.; Guo, X.; Song, C. Variation in the In₂O₃ Crystal Phase Alters Catalytic Performance toward the Reverse Water Gas Shift Reaction. ACS Catal. 2020, 10 (5), 3264-3273.
(35) Jacobs-Gedrim, R. B.; Shanmugam, M.; Jain, N.; Durcan, C. A.; Murphy, M. T.; Murray, T. M.; Matyi, R. J.; Moore, R. L.; Yu, B. Extraordinary Photoresponse in Two-Dimensional In₂Se₃ Nanosheets. ACS Nano 2014, 8 (1), 514-521.
(36) Suzuki, N.; Nagai, Y.; Itoh, Y.; Goto, A.; Yano, Y.; Hyodo, T. Vacancy Formation Energy for Indium Determined by a Positron Annihilation Technique. Phys. Rev. B: Condens. Matter Mater. Phys. 2001, 63 (18), 180101.
(37) Ma, D.; Li, T.; Yuan, D.; He, C.; Lu, Z.; Lu, Z.; Yang, Z.; Wang, Y. The Role of the Intrinsic Se and In Vacancies in the Interaction of O₂ and H₂O Molecules with the InSe Monolayer. Appl. Surf Sci. 2018, 434, 215-227.
(38) Igo, J.; Zhou, S.; Yu, Z. G.; Amnuayphol, O. P.; Zhao, F.; Gu, Y. Anharmonic Phonon Coupling in Single-Crystal Semiconducting and Metal-Like van Der Waals In₂Se₃. J. Phys. Chem. C 2018, 122 (40), 22849-22855.
(39) Seo, S. Y.; Park, J.; Park, J.; Song, K.; Cha, S.; Sim, S.; Choi, S. Y.; Yeom, H. W.; Choi, H.; Jo, M.-H. Writing Monolithic Integrated Circuits on a Two-Dimensional Semiconductor with a Scanning Light Probe. Nat. Elect. 2018, 1 (9), 512-517.
(40) Igo, J.; Gabel, M.; Yu, Z. G.; Yang, L.; Gu, Y. Photodefined In-Plane Heterostructures in Two-Dimensional In₂Se₃ Nanolayers for Ultrathin Photodiodes. ACS Appl. Nano Mater. 2019, 2 (10), 6774-6782.
(41) Sharma, T.; Sharma, R.; Tamboli, R. A.; Kanhere, D. G. Ab Initio Investigation of Structural and Electronic Properties of Selenium and Tellurium Clusters. Eur. Phys. J. B 2019, 92 (3), 51.
(42) Ho, C. H.; Lin, C. H.; Wang, Y. P.; Chen, Y. C.; Chen, S. H.; Huang, Y. S. Surface Oxide Effect on Optical Sensing and Photoelectric Conversion of α-In₂Se₃ Hexagonal Microplates. ACS Appl. Mater. Interfaces 2013, 5 (6), 2269-2277.
(43) Ho, C. H.; Lin, M. H.; Pan, C. C. Optical-Memory Switching and Oxygen Detection Based on the CVT Grown γ- and α-Phase In₂Se₃. Sens. Actuators, B 2015, 209, 811-819.
(44) Mafi, E.; Soudi, A.; Gu, Y. Electronically Driven Amorphization in Phase-Change In₂Se₃ Nanowires. J. Phys. Chem. C 2012, 116 (42), 22539-22544.
(45) Koren, E.; Berkovitch, N.; Rosenwaks, Y. Measurement of Active Dopant Distribution and Diffusion in Individual Silicon Nanowires. Nano Lett. 2010, 10 (4), 1163-1167.
(46) Koren, E.; Hyun, J. K.; Givan, U.; Hemesath, E. R.; Lauhon, L. J.; Rosenwaks, Y. Obtaining Uniform Dopant Distributions in VLS-Grown Si Nanowires. Nano Lett. 2011, 11 (1), 183-187.
(47) Koren, E.; Rosenwaks, Y.; Allen, J. E.; Hemesath, E. R.; Lauhon, L. J. Nonuniform Doping Distribution along Silicon Nanowires Measured by Kelvin Probe Force Microscopy and Scanning Photocurrent Microscopy. Appl. Phys. Lett. 2009, 95 (9), 092105.
(48) Koren, E.; Berkovitch, N.; Azriel, O.; Boag, A.; Rosenwaks, Y.; Hemesath, E. R.; Lauhon, L. J. Direct Measurement of Nanowire Schottky Junction Depletion Region. Appl. Phys. Lett. 2011, 99 (22), 223511.
(49) Mukherjee, S.; Maiti, R.; Katiyar, A. K.; Das, S.; Ray, S. K. Novel Colloidal MoS₂ Quantum Dot Heterojunctions on Silicon Platforms for Multifunctional Optoelectronic Devices. Sci. Rep. 2016, 6 (1), 29016.
(50) Mukherjee, S.; Das, K.; Das, S.; Ray, S. K. Highly Responsive, Polarization Sensitive, Self-Biased Single GeO₂—Ge Nanowire Device for Broadband and Low Power Photodetectors. ACS Photonics 2018, 5 (10), 4170-4178.
(51) Mech, R. K.; Mohta, N.; Chatterjee, A.; Selvaraja, S. K.; Muralidharan, R.; Nath, D. N. High Responsivity and Photovoltaic Effect Based on Vertical Transport in Multilayer α-In₂Se₃. physica status solidi (a) 2020, 217 (5), 1900932.
(52) Gurarslan, A.; Yu, Y.; Su, L.; Yu, Y.; Suarez, F.; Yao, S.; Zhu, Y.; Ozturk, M.; Zhang, Y.; Cao, L. Surface-Energy-Assisted Perfect Transfer of Centimeter-Scale Monolayer and Few-Layer MoS₂ Films onto Arbitrary Substrates. ACS Nano 2014, 8 (11), 11522-11528.
(53) Yalon, E.; Aslan, O. B.; Smithe, K. K. H.; McClellan, C. J.; Suryavanshi, S. V.; Xiong, F.; Sood, A.; Neumann, C. M.; Xu, X.; Goodson, K. E.; Heinz, T. F.; Pop, E. Temperature-Dependent Thermal Boundary Conductance of Monolayer MoS₂ by Raman Thermometry. ACS Appl. Mater. Interfaces 2017, 9 (49), 43013-43020.
(54) Kargar, F.; Coleman, E. A.; Ghosh, S.; Lee, J.; Gomez, M. J.; Liu, Y.; Magana, A. S.; Barani, Z.; Mohammadzadeh, A.; Debnath, B.; Wilson, R. B.; Lake, R. K.; Balandin, A. A. Phonon and Thermal Properties of Quasi-Two-Dimensional FePS₃ and MnPS₃ Antiferromagnetic Semiconductors. ACS Nano 2020, 14 (2), 2424-2435.
(55) Zhou, S.; Tao, X.; Gu, Y. Thickness-Dependent Thermal Conductivity of Suspended Two-Dimensional Single-Crystal In₂Se₃ Layers Grown by Chemical Vapor Deposition. J. Phys. Chem. C 2016, 120 (9), 4753-4758.

What is claimed is:

1. A monolithic solid state system, comprising a ferroelectric crystal and a semiconductor crystal arranged laterally to define a nanolayer having a heterojunction between said crystals, said nanolayer comprising at most 250 monolayers of said ferroelectric crystal.

2. The system according to claim 1, wherein said nanolayer comprise at most 200 monolayers of said ferroelectric crystal.

3. The system according to claim 1, wherein said nanolayer comprise at most 120 monolayers of said ferroelectric crystal.

4. A monolithic solid state system, comprising a ferroelectric crystal and a semiconductor crystal arranged laterally to define a nanolayer having a heterojunction between said crystals, said nanolayer having a thickness of at most 500 nm.

5. The system according to claim 1, wherein said ferroelectric crystal is polarized such that an internal electric field induced by said polarization comprises a component perpendicular to said heterojunction.

6. The system according to claim 1, wherein said nanolayer is planar.

7. The system according to claim 1, wherein said a semiconductor crystal is an oxide.

8. The system according to claim 7, wherein said oxide is formed by oxidation of said ferroelectric crystal.

9. The system according to claim 7, wherein said ferroelectric crystal comprises In₂Se₃, and said semiconductor crystal comprises In₂O₃.

10. The system according to claim 1, wherein said ferroelectric crystal comprises Pb(ZrₓTi₁₋ₓ)O₃.

11. The system according to claim 10, wherein said x is about 0.96.

12. The system according to claim 1, wherein said ferroelectric crystal comprises LiAlTe₂.

13. The system according to claim 1, wherein said ferroelectric crystal comprises CuInP₂S₆.

14. A method of configuring a solid state system, comprising
providing the solid state system according to claim 1; and
applying an electric field to said ferroelectric crystal so as to polarize said ferroelectric crystal in a direction parallel to said nanolayer.

15. An integrated circuit, comprising the system according to claim 1, and a plurality of contacts in electrical communication with said heterojunction.

16. The integrated circuit according to claim 15, comprising an electrode positioned to apply an electric field to said ferroelectric crystal so as polarize said ferroelectric crystal along a direction parallel to said nanolayer, wherein said applied electric field has a component perpendicular to said nanolayer.

17. An appliance system, comprising the integrated circuit according to claim 15, said appliance system being selected from the group consisting of a diode system, a transistor system, a memory system, an imaging system, a display system, a projector display system, an identification tag system, a sensor, and a photodetector.

18. A method of sensing, comprising directing light to the photodetector of claim 17, and receiving electrical signal via said contacts.

19. The method of claim 18, being executed without applying bias voltage to said heterojunction.

20. A method of fabricating a monolithic heterojunction, the method comprising:
selectively irradiating a region of nanolayer having at most 250 monolayers of a ferroelectric crystal by light such as to convert said ferroelectric crystal in said region into a semiconductor crystal by photo-thermal oxidation,
thereby forming a heterojunction between said semiconductor crystal in said region and said ferroelectric crystal in other regions of said nanolayer.
